(19) United States
(12) Patent Application Publication
(10) Pub. No.: US 2026/0193768 A1
(43) Pub. Date: Jul. 9, 2026

(54) DEPOSITION MASK, METHOD OF MANUFACTURING THE SAME, AND ELECTRONIC DEVICE MANUFACTURED BY USING THE SAME

(71) Applicant: Samsung Display Co., Ltd., Yongin-si (KR)

(72) Inventors: Ji Hyun JUNG, Yongin-si (KR); Jeong Kuk KIM, Yongin-si (KR); Duck Jung LEE, Yongin-si (KR); Yeon Woo LEE, Yongin-si (KR); Jun Ho JO, Yongin-si (KR)

(21) Appl. No.: 19/289,285

(22) Filed: Aug. 4, 2025

(30) Foreign Application Priority Data
Jan. 6, 2025 (KR) 10-2025-0001417

(51) Int. Cl. C23C 14/04; C23C 14/12; H10K 71/16

(52) U.S. Cl. CPC C23C 14/042; C23C 14/12; H10K 71/166

(57) ABSTRACT

A deposition mask, a method of manufacturing the deposition mask, and an electronic device manufactured by using the deposition mask are provided. The deposition mask includes a mask substrate having a cell opening, a membrane on a front surface of the mask substrate and having a plurality of pixel openings communicating with the cell opening, and a rear inorganic film on a rear surface of the mask substrate and having a rear opening communicating with the cell opening. The rear opening has a width equal to or greater than a width of the cell opening.

### CROSS-REFERENCE TO RELATED APPLICATION

The present application claims priority to and the benefit of Korean Patent Application No. 10-2025-0001417, filed on Jan. 6, 2025, in the Korean Intellectual Property Office, the entire content of which is incorporated herein by reference.

### BACKGROUND

### 1. Field

One or more embodiments of the present disclosure relate to a deposition mask, a method of manufacturing the same, and an electronic device manufactured by utilizing the same.

### 2. Description of the Related Art

Wearable devices that focus images at a short distance from the user's eyes have been developed in the form of glasses or helmets. For example, such wearable devices may include head-mounted displays (HMDs) and/or augmented reality (AR) glasses. These devices may provide augmented reality (AR) and/or virtual reality (VR) displays to users.

In wearable devices such as HMDs and/or AR glasses, a display resolution of approximately (about) 3000 pixels per inch (PPI) or higher is often desired or even required to enable prolonged use without causing dizziness or visual discomfort. To achieve such high resolution, organic light-emitting diode on silicon (OLEDoS) technology has emerged as a promising solution for high-resolution, small-form-factor displays. OLEDoS involves arranging organic light-emitting diodes (OLEDs) on a semiconductor substrate that includes complementary metal-oxide-semiconductor (CMOS) elements.

To manufacture a display panel with a high resolution of about 3000 PPI or higher, a high-resolution deposition mask is desired or required. For example, the deposition mask may be manufactured or fabricated by forming a membrane having a plurality of pixel openings on a front surface of a mask substrate, and then partially removing the mask substrate to form cell openings that expose the pixel openings. The cell openings may be formed by forming or depositing a rear inorganic film with rear openings on the rear surface of the mask substrate, followed by an etching process utilizing the rear inorganic film as an etching mask. During the etching process, undercut structures have a ring shape (e.g., ring-shaped undercut structures or undercuts) may be formed between the cell openings and the rear inorganic film.

### SUMMARY

Aspects and features of embodiments of the present disclosure are directed toward a deposition mask from which undercut structures are removed, a method of manufacturing the same, and an electronic device manufactured by utilizing the same.

However, embodiments of the present disclosure are not limited to those set forth herein. The above and additional aspects and features of embodiments of the present disclosure will become more apparent to one of ordinary skill in the art to which the present disclosure pertains by referencing the detailed description of the present disclosure provided herein or by learning by practice of the presented embodiments of the disclosure.

In accordance with one or more embodiments of the present disclosure, a deposition mask may include a mask substrate having a cell opening, a membrane on (e.g., arranged on) a front surface of the mask substrate and having a plurality of pixel openings communicating with the cell opening, and a rear inorganic film on (e.g., arranged on) a rear surface of the mask substrate and having a rear opening communicating with the cell opening. The rear opening may have a width equal to or greater than a width of the cell opening.

In accordance with one or more embodiments, the width of the cell opening may include a front width adjacent to the membrane and a rear width adjacent to the rear inorganic film, and the width of the rear opening may be equal to or greater than the rear width of the cell opening.

In accordance with one or more embodiments, the width of the cell opening may decrease from the rear surface of the mask substrate toward the front surface of the mask substrate, the front surface being adjacent to the membrane.

In accordance with one or more embodiments, the deposition mask may further include an intermediate inorganic film between (e.g., arranged between) the mask substrate and the rear inorganic film and having an intermediate opening between (e.g., arranged between) the cell opening and the rear opening. The intermediate opening may have a width equal to or greater than the width of the cell opening.

In accordance with one or more embodiments, wherein the width of the rear opening may be equal to the width of the intermediate opening.

In accordance with one or more embodiments, the deposition mask may further include a buffer inorganic film between (e.g., arranged between) the mask substrate and the membrane and having a buffer opening between (e.g., arranged between) the cell opening and the pixel openings. In this regard, the intermediate inorganic film may include a same material as the buffer inorganic film.

In accordance with one or more embodiments, the mask substrate may have a ring-shaped groove in (e.g., formed in) a rear portion of the mask substrate to surround the cell opening.

In accordance with one or more embodiments, the groove (i.e., ring-shaped groove) may be exposed by the rear opening.

In accordance with one or more embodiments of the present disclosure, a method of manufacturing a deposition mask may include forming a membrane having a plurality of pixel openings on a front surface of a mask substrate, forming a rear inorganic film on a rear surface of the mask substrate, partially removing the rear inorganic film to form a rear opening, and partially removing the mask substrate to form a cell opening between the pixel openings and the rear opening. The rear opening may have a width equal to or greater than a width of the cell opening.

In accordance with one or more embodiments, the method may further include forming an intermediate inorganic film on the rear surface of the mask substrate. In such embodiments, the rear inorganic film may be formed on the intermediate inorganic film.

In accordance with one or more embodiments, the method may further include partially removing the rear inorganic film to form a preliminary rear opening having a smaller width than the rear opening.

In accordance with one or more embodiments, the method may further include partially removing the intermediate inorganic film to form a preliminary intermediate opening having a same width as the preliminary rear opening. In such embodiments, the preliminary intermediate opening and the rear opening may be formed concurrently (e.g., simultaneously).

In accordance with one or more embodiments, the method may further include forming a photoresist pattern having a pattern opening including a first opening corresponding to the rear opening and a second opening corresponding to the preliminary intermediate opening on the rear inorganic film. In such embodiments, the preliminary rear opening, the preliminary intermediate opening, and the rear opening may be formed by an anisotropic etching process using the photoresist pattern as an etching mask.

In accordance with one or more embodiments, the photoresist pattern may be formed by a photolithography process using a halftone mask.

In accordance with one or more embodiments, while forming the cell opening, a portion of the intermediate inorganic film defining the preliminary intermediate opening may be exposed, and an undercut structure may be formed between the cell opening and the exposed portion of the intermediate inorganic film.

In accordance with one or more embodiments, the method may further include removing the exposed portion of the intermediate inorganic film to form an intermediate opening between the cell opening and the rear opening.

In accordance with one or more embodiments, the method may further include partially removing the intermediate inorganic film to form a preliminary intermediate opening having a smaller width than the rear opening.

In accordance with one or more embodiments, the method may further include forming a first photoresist pattern exposing a portion where the rear opening is to be formed, and the rear opening may be formed such that the intermediate inorganic film is exposed by an anisotropic etching process using the first photoresist pattern as an etching mask.

In accordance with one or more embodiments, the method may further include forming a second photoresist pattern exposing a portion where the preliminary intermediate opening is to be formed, and the preliminary intermediate opening may be formed such that the mask substrate is exposed by an anisotropic etching process using the second photoresist pattern as an etching mask.

In accordance with one or more embodiments, the method may further include partially removing a rear inorganic film to form a first preliminary rear opening, a second preliminary rear opening in a ring shape around (e.g., surrounding) the first preliminary rear opening, and a rear pattern in a ring shape defined by the first preliminary rear opening and the second preliminary rear opening, and partially removing the intermediate inorganic film to form a first preliminary intermediate opening, a second preliminary intermediate opening in a ring shape around (e.g., surrounding) the first preliminary intermediate opening, and an intermediate pattern in a ring shape defined by the first preliminary intermediate opening and the second preliminary intermediate opening.

In accordance with one or more embodiments, the cell opening may be formed by removing a portion of the mask substrate exposed by the first preliminary rear opening and the first preliminary intermediate opening.

In accordance with one or more embodiments, while forming the cell opening, an undercut structure may be formed between the cell opening and the intermediate pattern.

In accordance with one or more embodiments, the method may further include removing a portion of the mask substrate exposed by the second preliminary rear opening and the second preliminary intermediate opening to form a ring-shaped groove around (e.g., surrounding) the cell opening.

In accordance with one or more embodiments, the method may further include removing the intermediate pattern to form an intermediate opening including the first preliminary intermediate opening and the second preliminary intermediate opening.

In accordance with one or more embodiments, the rear pattern may be separated and removed from the mask substrate by removing the intermediate pattern, and the rear opening may be formed to include the first preliminary rear opening and the second preliminary rear opening as the rear pattern is removed from the mask substrate.

In accordance with one or more embodiments of the present disclosure, an electronic device may include a display panel. The display panel may include a backplane substrate and light emitting layers formed on the backplane substrate using a deposition mask. In such embodiments, the deposition mask may include a mask substrate having a cell opening, a membrane on (e.g., arranged on) a front surface of the mask substrate and having a plurality of pixel openings communicating with the cell opening, and a rear inorganic film on (e.g., arranged on) a rear surface of the mask substrate and having a rear opening communicating with the cell opening. The rear opening may have a width equal to or greater than a width of the cell opening.

In accordance with one or more embodiments, the electronic device may further include at least one of a processor, a memory, or a power module.

According to the embodiments described above, the undercut structure between the cell opening of the mask substrate and the rear inorganic film may be removed. Therefore, damage to the rear inorganic film may be prevented or reduced during a deposition process that uses the deposition mask or an ultrasonic cleaning process for cleaning the deposition mask. In addition, the amount of deposition materials blocked by the rear inorganic film may be reduced during the deposition process, thereby improving the uniformity and efficiency of material deposition onto the target substrate.

For example, by forming the deposition mask such that the rear opening has a width equal to or greater than the width of the corresponding cell opening, and by precisely aligning the rear, intermediate, and cell openings, both the structure and the manufacturing method contribute to improved dimensional accuracy and structural integrity. These features are achieved through a controlled multi-layer etching process that utilizes anisotropic etching techniques and photoresist patterning to ensure vertical alignment and prevent the formation of undercut structures. As a result, the deposition mask enables an unobstructed material deposition path, which enhances pattern fidelity and resolution—particularly in high-resolution applications such as OLEDoS-based AR and/or VR displays. Additionally, the improved structural configuration supports consistent manufacturing yields, reduces the risk of damage during cleaning or use, and extends the operational lifespan of the mask.

Other features and embodiments of the present disclosure may be apparent to those skilled in the art from the following detailed description and the drawings.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings, in which:

FIG. 1 is a block diagram of an electronic device according to one or more embodiments of the present disclosure;

FIG. 2 is a schematic diagram illustrating electronic devices according to one or more embodiments of the present disclosure;

FIG. 3 is an exploded perspective view illustrating a display device according to one or more embodiments of the present disclosure;

FIG. 4 is a block diagram illustrating the display device shown in FIG. 3 according to one or more embodiments of the present disclosure;

FIG. 5 is an equivalent circuit diagram illustrating an example of a first sub-pixel shown in FIG. 4 according to one or more embodiments of the present disclosure;

FIG. 6 is a schematic plan view illustrating an example of a display panel shown in FIG. 3 according to one or more embodiments of the present disclosure;

FIG. 7 is a schematic enlarged plan view illustrating an example of a display area shown in FIG. 6 according to one or more embodiments of the present disclosure;

FIG. 8 is a schematic enlarged plan view illustrating another example of the display area shown in FIG. 6 according to one or more embodiments of the present disclosure;

FIG. 9 is a schematic cross-sectional view illustrating an example of the display panel taken along the line I1-I1′ shown in FIG. 7 according to one or more embodiments of the present disclosure;

FIG. 10 is a schematic cross-sectional view illustrating another example of the display panel taken along the line I1-I1′ shown in FIG. 7 according to one or more embodiments of the present disclosure;

FIG. 11 is a schematic perspective view illustrating an example of a head mounted display according to one or more embodiments of the present disclosure;

FIG. 12 is a schematic exploded perspective view illustrating the head mounted display shown in FIG. 11 according to one or more embodiments of the present disclosure;

FIG. 13 is a schematic perspective view illustrating another example of the head mounted display according to one or more embodiments of the present disclosure;

FIG. 14 is a schematic diagram illustrating a deposition mask and a deposition apparatus including the deposition mask according to one or more embodiments of the present disclosure;

FIG. 15 is a schematic bottom view illustrating the backplane substrate shown in FIG. 14 according to one or more embodiments of the present disclosure;

FIG. 16 is a schematic plan view illustrating the deposition mask shown in FIG. 14 according to one or more embodiments of the present disclosure;

FIG. 17 is a schematic enlarged plan view illustrating mask cell regions shown in FIG. 16 according to one or more embodiments of the present disclosure;

FIG. 18 is a schematic cross-sectional view taken along the line I2-I2′ shown in FIG. 17 according to one or more embodiments of the present disclosure;

FIG. 19 is an enlarged cross-sectional view schematically illustrating the cell opening, the intermediate opening, and the rear opening shown in FIG. 18 according to one or more embodiments of the present disclosure;

FIG. 20 is a schematic enlarged cross-sectional view illustrating another example of the intermediate opening and the rear opening shown in FIG. 19 according to one or more embodiments of the present disclosure;

FIGS. 21-29 are schematic enlarged cross-sectional views illustrating a method of manufacturing a deposition mask according to one or more embodiments of the present disclosure;

FIGS. 30-33 are schematic enlarged cross-sectional views illustrating a method of manufacturing a deposition mask according to one or more embodiments of the present disclosure; and

FIGS. 34-38 are schematic enlarged cross-sectional views illustrating a method of manufacturing a deposition mask according to one or more embodiments of the present disclosure.

### DETAILED DESCRIPTION

The present disclosure will now be described more fully hereinafter with reference to the accompanying drawings, in which one or more embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that if (e.g., when) an element or a layer is referred to as being “on” another element or layer, it may be directly on the other element or layer, or one or more intervening layers may also be present therebetween. In contrast, “directly on” may refer to that there are no additional intervening elements or layers between the element or layer and the another element or layer. The same or like reference numbers indicate the same or like components throughout the disclosure.

It will be understood that, although the terms “first,” “second,” and/or the like may be used herein to describe one or more suitable elements, these elements should not be limited by these terms. These terms are only used to distinguish one element from another element. For instance, a first element discussed herein could be termed a second element without departing from the teachings of the present disclosure. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both (e.g., simultaneously) the singular and plural, unless the context clearly indicates otherwise. For example, “an element” has the same meaning as “at least one element,” unless the context clearly indicates otherwise. “At least one” is not to be construed as limiting “a” or “an.” “Or” may refer to “and/or.” As used herein, the term “and/or” includes any and all combinations of one or more of the associated listed items. It will be further understood that the terms “comprise(s)/comprising” and/or “include(s)/including” and/or “has(have)/having” if (e.g., when) used in this disclosure, specify the presence of stated features, regions, numbers, steps, operations, elements, and/or components, but do not preclude the presence or addition of one or more other features, regions, numbers, steps, operations, elements, components, and/or groups thereof. Additionally, the terms “comprise(s)/comprising,” “include(s)/including,” “has(have)/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof. Further, the use of “may” when describing embodiments of the present disclosure refers to “one or more embodiments of the present disclosure”.

Furthermore, relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in one of the drawings is turned over, e.g., upside down, elements described as being on the “lower” side of other elements would then be oriented on “upper” sides of the other elements. The term “lower,” may, therefore, encompasses both (e.g., simultaneously) an orientation of “lower” and “upper,” depending on the particular orientation of the drawing. Similarly, if the device in one of the drawings is turned over, e.g., upside down, elements described as “below” or “beneath” other elements would then be oriented “above” the other elements. The terms “below” or “beneath” may, therefore, encompass both (e.g., simultaneously) an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and may refer to within an acceptable range of deviation for the particular value as determined by one of ordinary skill in the art, considering the measurement in question and the error associated with measurement of the particular quantity (i.e., the limitations of the measurement system). For example, “about” may refer to within one or more standard deviations, or within ±30%, 20%, 10%, or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of one or more embodiments of the disclosure. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded in one or more embodiments. Thus, the regions illustrated in the drawings are schematic in nature and their shapes are not intended to illustrate the precise shape of a region and are not intended to limit the scope of the present claims.

Hereinafter, one or more embodiments will be described in more detail with reference to the accompanying drawings.

A display device according to one or more embodiments of the present disclosure may be applied to one or more suitable electronic devices. The electronic device according to one or more embodiments of the present disclosure includes the display device described herein, and may further include modules or devices having additional functions in addition to the display device.

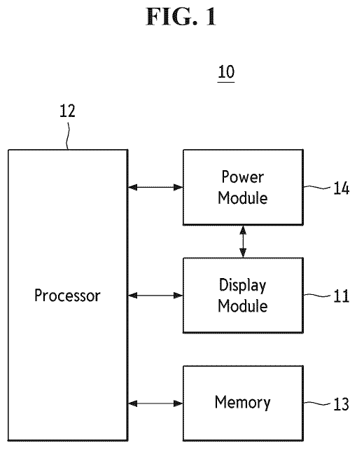

FIG. 1 is a block diagram of an electronic device according to one or more embodiments of the present disclosure.

Referring to FIG. 1, an electronic device 10 according to one or more embodiments of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for operations of the processor 12 and/or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as, for example, a power adapter or a battery, and a power conversion module that converts the power supplied by the power supply module to generate power necessary for the operation of the electronic device 10.

At least one of the components of the electronic device 10 according to one or more embodiments of the present disclosure may be included in a display device 20, which will be described later, according to one or more embodiments of the present disclosure. In addition, some modules of the individual modules functionally included in one module may be included in the display device 20, and other modules may be provided separately from the display device 20. For example, the display device 20 may include the display module 11, and the processor 12, the memory 13, and the power module 14 may be provided in the form of other devices within the electronic device 10 other than the display device 20.

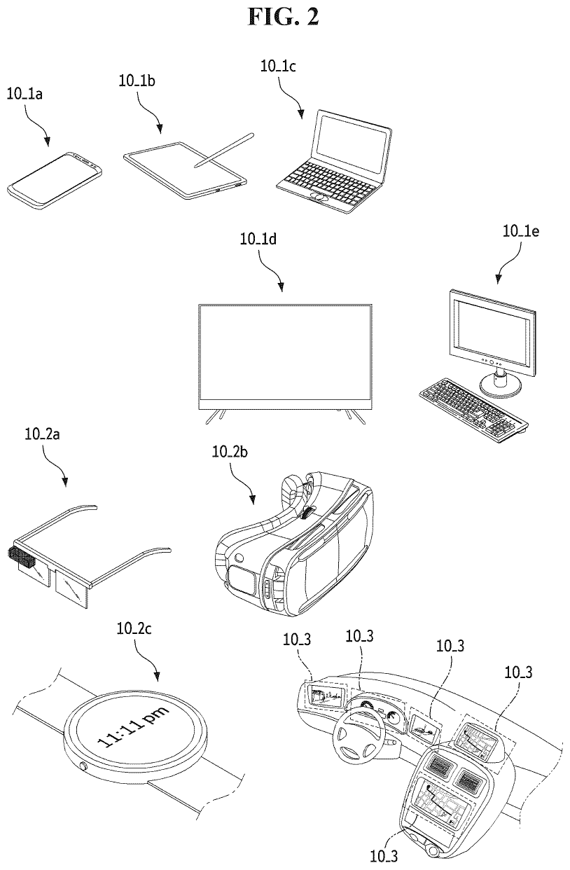

FIG. 2 is a schematic diagram illustrating electronic devices according to one or more embodiments of the present disclosure.

Referring to FIG. 2, one or more suitable electronic devices to which display devices 20 according to one or more embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example, smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

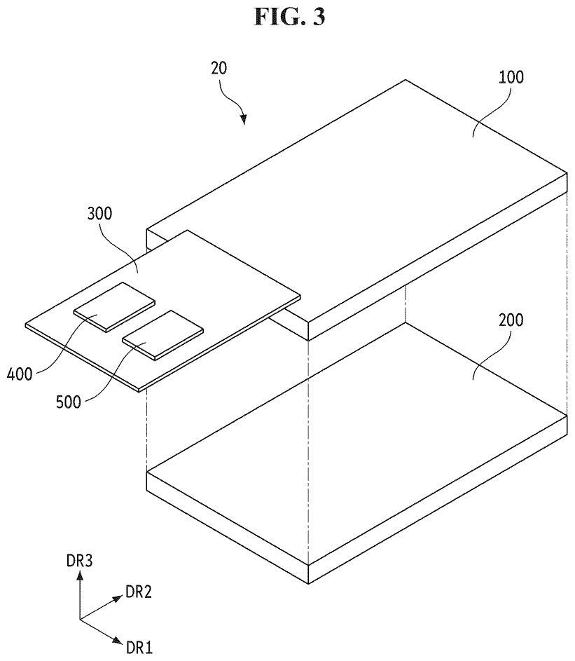

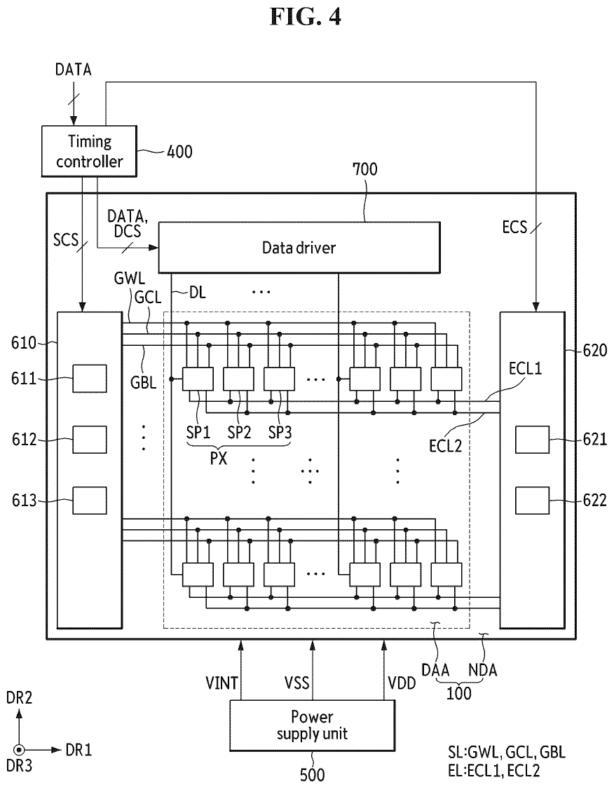

FIG. 3 is an exploded perspective view illustrating a display device according to one or more embodiments of the present disclosure. FIG. 4 is a block diagram illustrating the display device shown in FIG. 3 according to one or more embodiments.

Referring to FIG. 3 and FIG. 4, a display device 20 according to one or more embodiments may be a device displaying a moving image or a still image. A display device 20 according to one or more embodiments may be used as the electronic device 10 or the display module 11 of the electronic device 10. For example, the display device 20 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. The display device 20 according to one or more embodiments may be applied as a display module 11 of electronic devices 10 such as a television, a laptop, a monitor, a billboard, or an Internet-of-Things (IoT) terminal, and/or the like. The display device 20 according to one or more embodiments may be applied to electronic devices 10 such as a smart watch, a watch phone, a head mounted display (HMD) for implementing virtual reality and/or augmented reality, and/or the like.

The display device 20 according to one or more embodiments may include a display panel 100, a heat dissipation layer 200, a circuit board 300, a timing control circuit 400, and a power supply circuit 500.

In one or more embodiments, the display panel 100 may have a planar shape, for example, similar to a quadrilateral shape. For example, the display panel 100 may have a planar shape, similar to a quadrilateral shape, that has a short side of a first direction DR1 and a long side of a second direction DR2 intersecting the first direction DR1. In the display panel 100, a corner where the short side in the first direction DR1 and the long side in the second direction DR2 meet may be right-angled or rounded with a set or predetermined curvature. The planar shape of the display panel 100 is not limited to a quadrilateral shape, and may be a shape similar to another polygonal shape, a circular shape, or an elliptical shape. A planar shape of the display device 20 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 4.

The plurality of pixels PX may be arranged in the display area DAA. In one or more embodiments, the plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged with one another in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

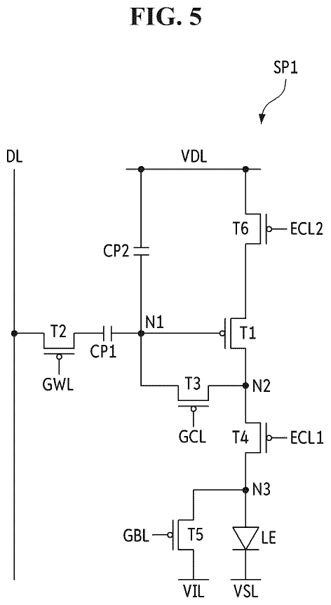

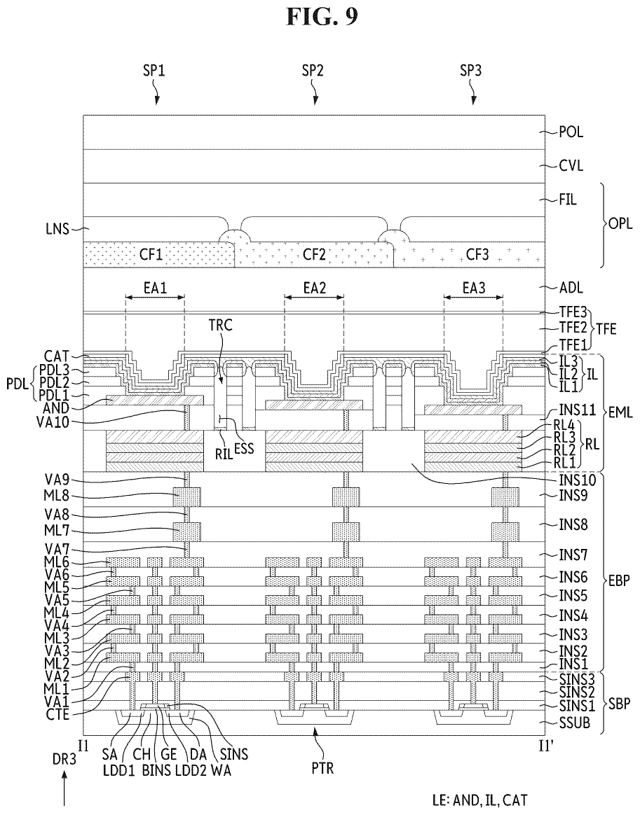

The plurality of pixels PX may include a plurality of sub-pixels SP1, SP2, and SP3. The plurality of sub-pixels SP1, SP2, and SP3 may each include a plurality of pixel transistors as shown in FIG. 5, and the plurality of pixel transistors may be formed by a semiconductor process and arranged on a semiconductor substrate SSUB (see FIG. 9). For example, in one or more embodiments, the plurality of pixel transistors of the data driver 700 may be formed of complementary metal oxide semiconductor (CMOS), but embodiments of the present disclosure are not limited thereto.

Each of the plurality of sub-pixels SP1, SP2, and SP3 may be connected to a (e.g., one) write scan line GWL, a (e.g., one) control scan line GCL, a (e.g., one) bias scan line GBL, a (e.g., one) first emission control line ECL1, a (e.g., one) second emission control line ECL2, and a (e.g., one) data line DL. Each of the plurality of sub-pixels SP1, SP2, and SP3 may receive a data voltage of the data line DL in response to a write scan signal of the write scan line GWL, and emit light from a light emitting element according to the data voltage.

In one or more embodiments, the scan driver 610, the emission driver 620, and the data driver 700 may each be arranged in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. For example, in one or more embodiments, the plurality of scan transistors and the plurality of light emitting transistors may be formed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit (i.e., timing controller) 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see FIG. 9) through a semiconductor process. For example, in one or more embodiments, the plurality of data transistors may be formed of CMOS, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this regard, the sub-pixels SP1, SP2, and SP3 may be selected by the write scan signal of the scan driver 610, and data voltages (e.g., analog data voltage) may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on a (e.g., one) surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), and/or aluminum (Al).

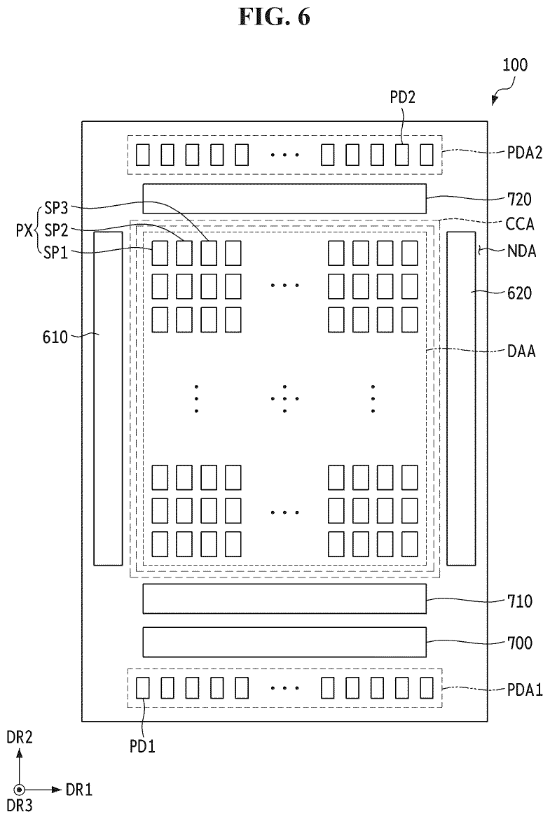

The circuit board 300 may be electrically connected to a plurality of first pads PD1 (see FIG. 6) of a first pad portion PDA1 (see FIG. 6) of the display panel 100 by using a conductive adhesive member such as an anisotropic conductive film. In one or more embodiments, the circuit board 300 may be a flexible printed circuit board with a flexible material, or a flexible film. Although the circuit board 300 is illustrated in FIG. 3 as being unfolded, the circuit board 300 may be bent. In this regard, one end of the circuit board 300 may be arranged on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. The one end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit (i.e., power supply unit) 500 may generate a plurality of panel driving voltages according to a power voltage from the outside. For example, in one or more embodiments, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

Each of the timing control circuit 400 and the power supply circuit 500 may be formed as an integrated circuit (IC) and attached to a (e.g., one) surface of the circuit board 300. In this regard, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100, similarly to the scan driver 610, the emission driver 620, and the data driver 700. In these embodiments, the timing control circuit 400 may include a plurality of timing transistors, and the power supply circuit 500 may include a plurality of power transistors. The plurality of timing transistors and the plurality of power transistors may be formed on the semiconductor substrate SSUB (see FIG. 9) through a semiconductor process. For example, in one or more embodiments, the plurality of timing transistors and the plurality of power transistors may be formed of CMOS, but embodiments of the present disclosure are not limited thereto. In one or more embodiments, each of the timing control circuit 400 and the power supply circuit 500 may be arranged between the data driver 700 and the first pad portion PDA1 (see FIG. 6).

FIG. 5 is an equivalent circuit diagram illustrating an example of a first sub-pixel shown in FIG. 4 according to one or more embodiments of the present disclosure.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In one or more embodiments, the first sub-pixel SP1 may include a plurality of transistors T1 to T6, a light emitting element LE, a first capacitor CP1, and a second capacitor CP2.

The light emitting element LE emits light in response to a driving current flowing through the channel of a first transistor T1. The emission amount (e.g., emission intensity) of the light emitting element LE may be proportional to the driving current. A first electrode of the light emitting element LE may be an anode electrode, and a second electrode of the light emitting element LE may be a cathode electrode. In one or more embodiments, the light emitting element LE may be an organic light emitting diode including a first electrode, a second electrode, and an organic light emitting layer arranged between the first electrode and the second electrode, but embodiments of the present disclosure are not limited thereto. For example, in one or more embodiments, the light emitting element LE may be an inorganic light emitting element including a first electrode, a second electrode, and an inorganic semiconductor arranged between the first electrode and the second electrode, in these embodiments, the light emitting element LE may be a micro light emitting diode.

The first transistor T1 may be a driving transistor that controls a source-drain current (hereinafter referred to as “driving current”) flowing between a source electrode and a drain electrode thereof according to a voltage applied to a gate electrode thereof.

A second transistor T2 may be arranged between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be arranged between a first node N1 and a second node N2. The third transistor T3 is turned on by the control scan signal of the control scan line GCL to connect the first node N1 to the second node N2. For this reason, if (e.g., when) the gate electrode and the drain electrode of the first transistor T1 are connected, the first transistor T1 may operate like a diode.

A fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be arranged between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

A sixth transistor T6 may be arranged between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and a drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, in one or more embodiments, each of the first to sixth transistors T1 to T6 may be a P-type (kind) MOSFET, but embodiments of the present disclosure are not limited thereto. In one or more embodiments, each of the first to sixth transistors T1 to T6 may be an N-type (kind) MOSFET. In one or more embodiments, some of the first to sixth transistors T1 to T6 may be P-type (kind) MOSFETs, and each of the remaining transistors may be an N-type (kind) MOSFET.

Although it is illustrated in FIG. 5 that the first sub-pixel SP1 includes six transistors T1 to T6 and two capacitors C1 and C2, it should be noted that the equivalent circuit diagram of the first sub-pixel SP1 is not limited to that shown in FIG. 5. For example, the number of transistors and the number of capacitors of the first sub-pixel SP1 are not limited to those shown in FIG. 5.

Further, the equivalent circuit diagram of the second sub-pixel SP2 and the equivalent circuit diagram of the third sub-pixel SP3 may each be substantially the same as the equivalent circuit diagram of the first sub-pixel SP1 described in conjunction with FIG. 5. Therefore, the description of the equivalent circuit diagram of the second sub-pixel SP2 and the equivalent circuit diagram of the third sub-pixel SP3 is not repeated in the present disclosure.

FIG. 6 is a schematic plan view illustrating an example of a display panel shown in FIG. 3 according to one or more embodiments of the present disclosure.

Referring to FIG. 6, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be arranged on a first side of the display area DAA, and the emission driver 620 may be arranged on a second side of the display area DAA. For example, in one or more embodiments, the scan driver 610 may be arranged on one side of the display area DAA in the first direction DR1, and the emission driver 620 may be arranged on the other side of the display area DAA in the first direction DR1. However, embodiments of the present disclosure are not limited thereto, for example, in one or more embodiments, the scan driver 610 and the emission driver 620 may be arranged on both (e.g., simultaneously) the first side and the second side of the display area DAA.

The first pad portion PDA1 may include the plurality of first pads PD1 connected to pads or bumps of the circuit board 300 through a conductive adhesive member. The first pad portion PDA1 may be arranged on a third side of the display area DAA. For example, in one or more embodiments, the first pad portion PDA1 may be arranged on one side of the display area DAA in the second direction DR2. The first pad portion PDA1 may be arranged outside the data driver 700 in the second direction DR2. For example, the first pad portion PDA1 may be arranged closer to an edge of the display panel 100 than the data driver 700 is. This refers to that the first pad portion PDA1 is located further towards the edge of the display panel compared to the data driver 700, ensuring that it is outside the area occupied by the data driver in the specified direction DR2. This positioning helps in connecting the first pads PD1 to the circuit board through a conductive adhesive member, facilitating the overall assembly and functionality of the display panel.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be arranged on a fourth side of the display area DAA. For example, the second pad portion PDA2 may be arranged on the other side of the display area DAA in the second direction DR2. The second pad portion PDA2 may be arranged outside the second distribution circuit 720 in the second direction DR2. For example, the second pad portion PDA2 may be arranged closer to an edge of the display panel 100 than the second distribution circuit 720 is.

The first distribution circuit 710 distributes data voltages applied through the first pad portion PDA1 to the plurality of data lines DL. For example, in one or more embodiments, the first distribution circuit 710 may distribute the data voltages applied through one first pad PD1 of the first pad portion PDA1 to P (P is a positive integer of 2 or more) data lines DL, and as a result, the number of the plurality of first pads PD1 may be reduced. The first distribution circuit 710 may be arranged on the third side of the display area DAA of the display panel 100. For example, the first distribution circuit 710 may be arranged on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be arranged on the fourth side of the display area DAA of the display panel 100. For example, the second distribution circuit 720 may be arranged on the other side of the display area DAA in the second direction DR2. In the context of the present disclosure and unless defined otherwise, “one side of the display area DAA in the second direction DR2” refers to a specific side of the display area along the direction labeled as DR2. For instance, if DR2 represents a vertical direction, this may indicate the bottom side of the display area. Conversely, “the other side of the display area DAA in the second direction DR2” refers to the opposite side of the display area along the same direction DR2, which, continuing the previous example, may indicate the top side of the display area. These phrases are used to describe the positioning of components, such as distribution circuits, on opposite sides of the display area along the specified direction DR2.

A cathode connection part CCA may be a region where a second electrode CAT (see FIG. 9) of a display element layer EML (see FIG. 9) is connected to the first driving voltage line VSL of the non-display area NDA. In one or more embodiments, the cathode connection part CCA may be arranged outside at least one side of the display area DAA. For example, the cathode connection part CCA may be arranged outside at least on one side selected from among the left side, the right side, the upper side, and the lower side of the display area DAA. In one or more embodiments, the cathode connection part CCA may be arranged to surround the display area DAA as shown in FIG. 6 in order to minimize or reduce a deviation in the first driving voltage VSS caused by voltage drop (IR drop) or voltage rise (IR rising) of the second electrode CAT in the display area DAA.

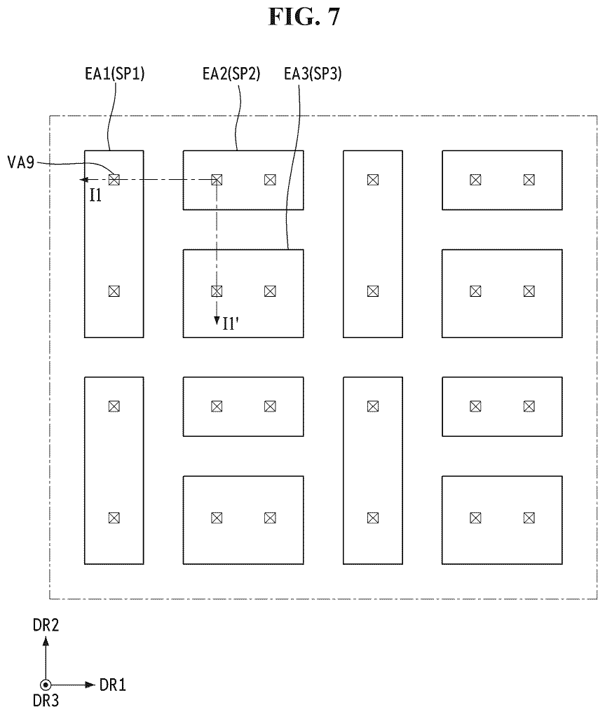

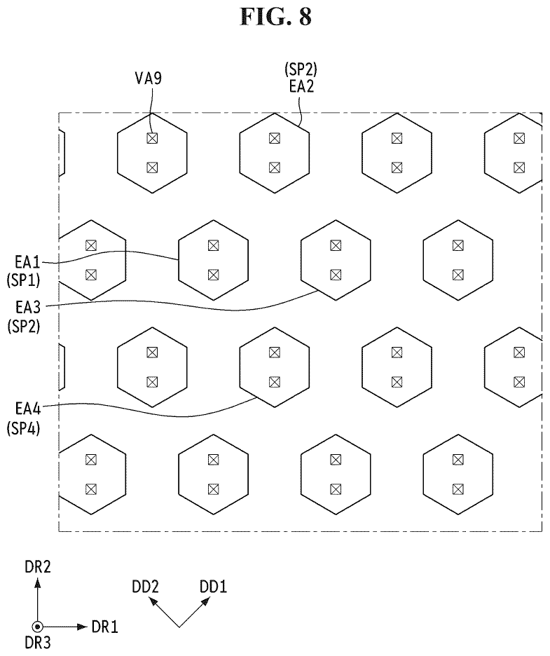

FIG. 7 is a schematic enlarged plan view illustrating an example of a display area shown in FIG. 6 according to one or more embodiments of the present disclosure. FIG. 8 is a schematic enlarged plan view illustrating another example of the display area shown in FIG. 6 according to one or more embodiments of the present disclosure.

Referring to FIG. 7 and FIG. 8, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3. Each of the first sub-pixel SP1, the second sub-pixel SP2, and the third sub-pixel SP3 may include a via VA9. For example, the via VA9 is a feature included in each of the sub-pixels, The detailed description of the via VA9 will be described in more detail later with reference to FIG. 9.

The first emission area EA1, the second emission area EA2, and the third emission area EA3 may each have, in plan view, a quadrilateral shape or a hexagonal shape as shown in FIG. 7 and FIG. 8, but embodiments of the present disclosure are not limited thereto. In one or more embodiments, the first emission area EA1, the second emission area EA2, and the third emission area EA3 may each independently have a polygonal shape other than a quadrangle shape or a hexagon shape, a circular shape, an elliptical shape, or an atypical shape in plan view.

As shown in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

In one or more embodiments, as shown in FIG. 8, the emission areas EA1, EA2, EA3, and EA4 may each have a hexagonal shape in plan view. In this regard, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may be to emit first light, the second sub-pixel SP2 may be to emit second light, and the third sub-pixel SP3 may be to emit third light. In one or more embodiments, the first light may be light of a blue wavelength band, the second light may be light of a green wavelength band, and the third light may be light of a red wavelength band. For example, the blue wavelength band may be a wavelength band of light whose main peak wavelength is in the range of approximately (about) 370 nanometers (nm) to 460 nm, the green wavelength band may be a wavelength band of light whose main peak wavelength is in the range of approximately (about) 480 nm to 560 nm, and the red wavelength band may be a wavelength band of light whose main peak wavelength is in the range of approximately (about) 600 nm to 750 nm.

As shown in FIG. 7, each of the plurality of pixels PX may include three emission areas EA1, EA2, and EA3, or may include four emission areas EA1, EA2, EA3, and EA4 as shown in FIG. 8. In this regard, the fourth emission area EA4 may be to emit the same second light as the second emission area EA2, but embodiments of the present disclosure are not limited thereto.

In one or more embodiments, the emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape. PenTile® is a duly registered trademark of Samsung Display Co., Ltd.

FIG. 9 is a schematic cross-sectional view illustrating an example of the display panel taken along the line I1-I1′ shown in FIG. 7 according to one or more embodiments.

Referring to FIG. 9, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may include (e.g., be) the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type (kind) impurity. A plurality of well regions WA may be arranged on a top surface of the semiconductor substrate SSUB. The plurality of well regions WA may be regions doped with a second type (kind) impurity. The second type (kind) impurity may be different from the first type (kind) impurity. For example, in one or more embodiments, if (e.g., when) the first type (kind) impurity is a p-type (kind) impurity, the second type (kind) impurity may be an n-type (kind) impurity. In one or more embodiments, if (e.g., when) the first type (kind) impurity is an n-type (kind) impurity, the second type (kind) impurity may be a p-type (kind) impurity.

Each of the plurality of well regions WA includes a source region SA corresponding to the source electrode of the pixel transistor PTR, a drain region DA corresponding to the drain electrode thereof, and a channel region CH arranged between the source region SA and the drain region DA.

A lower insulating film BINS may be arranged between a gate electrode GE and the well region WA. A side insulating film SINS may be arranged on a side surface of the gate electrode GE. The side insulating film SINS may be arranged on the lower insulating film BINS.

Each of the source region SA and the drain region DA may be a region doped with the first type (kind) impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be arranged on one side of the gate electrode GE, and the drain region DA may be arranged on the other side of the gate electrode GE.

Each of the plurality of well regions WA may further include a first low-concentration impurity region LDD1 arranged between the channel region CH and the source region SA, and a second low-concentration impurity region LDD2 arranged between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be arranged on the semiconductor substrate SSUB. A second semiconductor insulating film SINS2 may be arranged on the first semiconductor insulating film SINS1.

The plurality of contact terminals CTE may be arranged on the second semiconductor insulating film SINS2. Each of the plurality of contact terminals CTE may be connected to corresponding one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may each be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them.

A third semiconductor insulating film SINS3 may be arranged on a side surface of each of the plurality of contact terminals CTE. A top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be independently formed of silicon carbonitride (SiCN) or a silicon oxide (SiOx)-based inorganic film, but embodiments of the present disclosure are not limited thereto.

In one or more embodiments, the semiconductor substrate SSUB may be replaced with a glass substrate or a polymer resin substrate such as polyimide. In these embodiments, thin film transistors may be arranged on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of interlayer insulating films INS1 to INS9.

First to ninth interlayer insulating films INS1 to INS9 serve to insulate first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

For example, in one or more embodiments, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may be formed of substantially a same material. The first to eighth conductive layers ML1 to ML8 and the first to eighth vias VA1 to VA8 may be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them. The first to eighth vias VA1 to VA8 may be made of substantially the same material. In one or more embodiments, the first to eighth interlayer insulating films INS1 to INS8 may be formed of a silicon oxide (SiOₓ)-based inorganic layer, but embodiments of the present disclosure are not limited thereto.

The ninth interlayer insulating film INS9 may be arranged on the eighth interlayer insulating film INS8 and the eighth conductive layer ML8. The ninth interlayer insulating film INS9 may be formed of a silicon oxide (SiOₓ)-based inorganic film, but embodiments of the present disclosure are not limited thereto.

Each of the ninth vias VA9 may penetrate the ninth interlayer insulating film INS9 and be connected to the exposed eighth conductive layer ML8. The ninth vias VA9 may be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them.

The display element layer EML may be arranged on the light emitting element backplane EBP. The display element layer EML may include tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be arranged on the ninth interlayer insulating film INS9. Each of the reflective electrodes RL may include at least one selected from among reflective electrodes RL1, RL2, RL3, and RL4. For example, in one or more embodiments, each of the reflective electrodes RL may include first to fourth reflective electrodes RL1, RL2, RL3, and RL4 as shown in FIG. 9.

The first reflective electrodes RL1 may be arranged on the ninth interlayer insulating film INS9, and may be connected to the ninth via VA9. Each of the second reflective electrodes RL2 may be arranged on the first reflective electrode RL1 corresponding thereto. Each of the third reflective electrodes RL3 may be arranged on the second reflective electrode RL2 corresponding thereto. Each of the fourth reflective electrodes RL4 may be arranged on the third reflective electrode RL3 corresponding thereto.

Because the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them. For example, in one or more embodiments, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be arranged on the ninth interlayer insulating film INS9. The tenth interlayer insulating film INS10 may be arranged between the reflective electrodes RL adjacent to each other. The tenth interlayer insulating film INS10 may be a film for flattening a stepped portion caused by the reflective electrodes RL. The eleventh interlayer insulating film INS11 may be arranged on the tenth interlayer insulating film INS10 and the reflective electrodes RL.

In one or more embodiments, the tenth interlayer insulating film INS10 and the eleventh interlayer insulating film INS11 may each be formed of a silicon oxide (SiOₓ)-based inorganic film, but embodiments of the present disclosure are not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. For example, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, in one or more embodiments, as shown in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this regard, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed corresponding fourth reflective electrode RL4. The tenth vias VA10 may be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be arranged on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them. For example, in one or more embodiments, the first electrode AND of each of the light emitting elements LE may be titanium nitride (TiN).

The pixel defining film PDL may be arranged on a part of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is arranged.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be arranged on the edge of the first electrode AND of each of the light emitting elements LE, the second pixel defining film PDL2 may be arranged on the first pixel defining film PDL1, and the third pixel defining film PDL3 may be arranged on the second pixel defining film PDL2. In one or more embodiments, the first pixel defining film PDL1, the second pixel defining film PDL2, and the third pixel defining film PDL3 may each be formed of a silicon oxide (SiOₓ)-based inorganic film. In one or more embodiments, the first pixel defining film PDL1 and the third pixel defining film PDL3 may each be formed of a silicon nitride (SiNₓ)-based inorganic film, whereas the second pixel defining film PDL2 may be formed of a silicon oxide (SiOₓ)-based inorganic film. The first pixel defining film PDL1, the second pixel defining film PDL2, and the third pixel defining film PDL3 may each have a thickness of about 500 angstroms (Å).

In order to reduce or prevent or reduce the likelihood of a first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to a ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. In one or more embodiments, the eleventh interlayer insulating film INS11 may be partially recessed at each of the plurality of trenches TRC.

At least one trench TRC may be arranged between neighboring sub-pixels SP1, SP2, and SP3. Although FIG. 9 illustrates that two trenches TRC are arranged between the neighboring sub-pixels SP1, SP2, and SP3, embodiments of the present disclosure are not limited thereto.

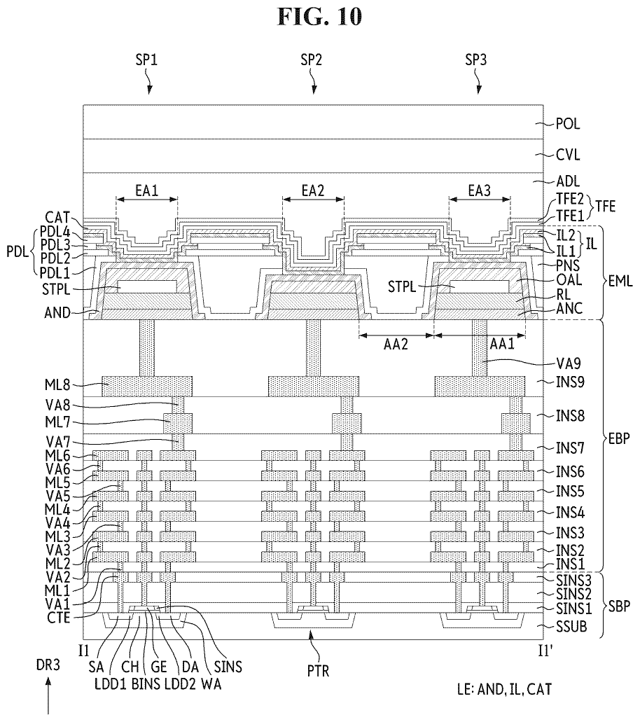

The light emitting stack IL may include a plurality of stack layers IL1, IL2, and IL3. FIG. 9 illustrates that the light emitting stack IL has a three-tandem structure including a first stack layer IL1, a second stack layer IL2, and a third stack layer IL3, but embodiments of the present disclosure are not limited thereto. For example, in one or more embodiments of the light emitting stack IL may have a two-tandem structure including two stack layers as shown in FIG. 10.

In the three-tandem structure, in one or more embodiments, the light emitting stack IL may have a tandem structure including a plurality of intermediate layers IL1, IL2, and IL3 that emit different lights. For example, the light emitting stack IL may include the first stack layer IL1 that is configured to emit first light, the second stack layer IL2 that is configured to emit second light, and the third stack layer IL3 that is configured to emit third light. The first stack layer IL1, the second stack layer IL2, and the third stack layer IL3 may be sequentially stacked (e.g., in the stated order).

The first stack layer IL1 may have a structure in which a first hole transport layer, a first light emitting layer that emits the first light, and a first electron transport layer are sequentially stacked (e.g., in the stated order). The second stack layer IL2 may have a structure in which a second hole transport layer, a second light emitting layer that emits the second light, and a second electron transport layer are sequentially stacked (e.g., in the stated order). The third stack layer IL3 may have a structure in which a third hole transport layer, a third light emitting layer that emits the third light, and a third electron transport layer are sequentially stacked (e.g., in the stated order).

In one or more embodiments, a first charge generation layer for supplying charges (e.g., holes) to the second stack layer IL2 and supplying electrons to the first stack layer IL1 may be arranged between the first stack layer IL1 and the second stack layer IL2. The first charge generation layer may include an N-type (kind) charge generation layer that supplies electrons to the first stack layer IL1 and a P-type (kind) charge generation layer that supplies holes to the second stack layer IL2. The N-type (kind) charge generation layer may include a dopant of a metal material.

A second charge generation layer for supplying charges (e.g., holes) to the third stack layer IL3 and supplying electrons to the second stack layer IL2 may be arranged between the second stack layer IL2 and the third stack layer IL3. The second charge generation layer may include an N-type (kind) charge generation layer that supplies electrons to the second stack layer IL2 and a P-type (kind) charge generation layer that supplies holes to the third stack layer IL3.

The first stack layer IL1 may be arranged on the first electrodes AND and the pixel defining film PDL, and a residual film RIL arranged on a bottom surface of each trench TRC may be a same material as the first stack layer IL1. Due to the trench TRC, the first stack layer IL1 may be cut off between neighboring sub-pixels SP1, SP2, and SP3. The second stack layer IL2 may be arranged on the first stack layer IL1. Due to the trench TRC, the second stack layer IL2 may be cut off between the neighboring sub-pixels SP1, SP2, and SP3. A cavity ESS or an empty space may be arranged between the residual film RIL and the second stack layer IL2 in the trench TRC. The third stack layer IL3 may be arranged on the second stack layer IL2. The third stack layer IL3 is not cut off by the trench TRC and may be arranged to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off a lower stack layer and a charge generation layer arranged between the lower stack layer and an upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, in one or more embodiments, instead of the trench TRC, a reverse tapered partition wall may be arranged on the pixel defining film PDL.

In addition, FIG. 9 illustrates that the light emitting stack IL that emits light is arranged in each of the first emission area EA1, the second emission area EA2, and the third emission area EA3, but embodiments of the present disclosure are not limited thereto. For example, in one or more embodiments, instead of the light emitting stack IL, the first light emitting layer may be arranged in the first emission area EA1, and may not be provided in the second emission area EA2 and the third emission area EA3. Furthermore, the second light emitting layer may be arranged in the second emission area EA2 and may not be provided in the first emission area EA1 and the third emission area EA3. Furthermore, the third light emitting layer may be arranged in the third emission area EA3 and may not be provided in the first emission area EA1 and the second emission area EA2. In these embodiments, first to third color filters CF1, CF2, and CF3 of the optical layer OPL may not be provided.

The second electrode CAT may be arranged on the light emitting stack IL. For example, the second electrode CAT may be arranged on the third stack layer IL3. In one or more embodiments, the second electrode CAT may be formed of a transparent conductive material (TCO) such as ITO or IZO that may transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be arranged on the display element layer EML. The encapsulation layer TFE may include at least one selected from among inorganic films TFE1 and TFE3 to prevent or reduce oxygen and/or moisture from permeating into the display element layer EML. For example, the encapsulation layer TFE includes at least one inorganic film, such as TFE1 or TFE3, to prevent or reduce the permeation of oxygen and/or moisture into the display element layer EML. For example, in one or more embodiments, the encapsulation layer TFE may include both a first encapsulation inorganic film TFE1 and a second encapsulation inorganic film TFE3. The first encapsulation inorganic film TFE1 may be arranged on the second electrode CAT, and the second encapsulation inorganic film TFE3 may be arranged above the first encapsulation inorganic film TFE1. The first encapsulation inorganic film TFE1 and the second encapsulation inorganic film TFE3 may each independently be formed of multiple layers in which one or more inorganic films selected from among silicon nitride (SiNₓ), silicon oxynitride (SiON), silicon oxide (SiOₓ), titanium oxide (TiOₓ), and aluminum oxide (AlOₓ) layers are alternately stacked.

In addition, the encapsulation layer TFE may include at least one organic film TFE2 to protect the display element layer EML from foreign substances such as dust. The encapsulating organic film TFE2 may be arranged between the first encapsulating inorganic film TFE1 and the second encapsulating inorganic film TFE3. In one or more embodiments, the encapsulation organic film TFE2 may be a monomer. In one or more embodiments, the encapsulation organic film TFE2 may be an organic film such as formed of an acryl resin, an epoxy resin, a phenolic resin, a polyamide resin, a polyimide resin, and/or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may each be arranged on the adhesive layer ADL.

The first color filter CF1 may overlap the first emission area EA1 of the first sub-pixel SP1. The first color filter CF1 may be to transmit light of the first color, i.e., light of a blue wavelength band. The blue wavelength band may be about 370 nm to about 460 nm. Thus, the first color filter CF1 may be to transmit light of the first color among light emitted from the first emission area EA1.

The second color filter CF2 may overlap the second emission area EA2 of the second sub-pixel SP2. The second color filter CF2 may be to transmit light of the second color, i.e., light of a green wavelength band. The green wavelength band may be about 480 nm to about 560 nm. Thus, the second color filter CF2 may be to transmit light of the second color among light emitted from the second emission area EA2.

The third color filter CF3 may overlap the third emission area EA3 of the third sub-pixel SP3. The third color filter CF3 may be to transmit light of the third color, i.e., light of a red wavelength band. The red wavelength band may be about 600 nm to about 750 nm. Thus, the third color filter CF3 may be to transmit light of the third color among light emitted from the third emission area EA3.

The plurality of lenses LNS may be arranged on the first color filter CF1, the second color filter CF2, and the third color filter CF3, respectively. Each of the plurality of lenses LNS may be a structure for increasing the proportion of light directed to the front of the display device 10. In one or more embodiments, each of the plurality of lenses LNS may have a cross-sectional shape that is convex in an upward direction.

The filling layer FIL may be arranged on the plurality of lenses LNS. The filling layer FIL may have a set or predetermined refractive index such that light travels in the third direction DR3 at an interface between the filling layer FIL and the plurality of lenses LNS. Further, the filling layer FIL may also be a planarization layer. The filling layer FIL may be an organic film such as formed of an acrylic resin, an epoxy resin, a phenolic resin, a polyamide resin, or a polyimide resin.

The cover layer CVL may be arranged on the filling layer FIL. The cover layer CVL may be a glass substrate or a polymer resin. In one or more embodiments, when the cover layer CVL is a glass substrate, it may be attached onto the filling layer FIL. In these embodiments, the filling layer FIL may serve to bond the cover layer CVL. When the cover layer CVL is a glass substrate, it may serve as an encapsulation substrate. In one or more embodiments, when the cover layer CVL is a polymer resin, it may be directly applied onto the filling layer FIL.

The polarizing plate may be arranged on a (e.g., one) surface of the cover layer CVL. The polarizing plate may be a structure for reducing or preventing visibility degradation caused by reflection of external light. The polarizing plate may include a linear polarizing plate and a phase retardation film. For example, in one or more embodiments, the phase retardation film may be a λ/4 plate (quarter-wave plate), but embodiments of the present disclosure are not limited thereto. However, if (e.g., when) visibility degradation caused by reflection of external light is sufficiently overcome by the first to third color filters CF1, CF2, and CF3, the polarizing plate may not be provided.

FIG. 10 is a schematic cross-sectional view illustrating another example of the display panel taken along the line I1-I1′ shown in FIG. 7 according to one or more embodiments of the present disclosure.

The embodiment of FIG. 10 differs from the embodiment of FIG. 9 in that the first electrode AND of each of the light emitting elements LE is in contact with and electrically connected to a side surface of a connection electrode ANC connected to the eighth conductive layer ML8. The embodiment of FIG. 10 also differs from the embodiment of FIG. 9 in that the trench TRC is not provided, and instead, the third pixel defining film PDL3 and a fourth pixel defining film PDL4 that has an eave-shaped or mushroom-shaped cross-sectional structure are provided. In describing one or more embodiments of FIG. 10, redundant description of parts already described in one or more embodiments of FIG. 9 will not be provided.

Referring to FIG. 10, in one or more embodiments, a plurality of connection electrodes ANC may be respectively arranged on first portions AA1 of the ninth interlayer insulating film INS9. Each of the plurality of connection electrodes ANC may be arranged on the first portion AA1 of the ninth interlayer insulating film INS9 corresponding thereto. The plurality of connection electrodes ANC may be formed of any one selected from among copper (Cu), aluminum (Al), tungsten (W), molybdenum (Mo), chromium (Cr), gold (Au), titanium (Ti), nickel (Ni), and neodymium (Nd), an alloy or a compound including any one of them, or a transparent conductive oxide. For example, in one or more embodiments, the plurality of connection electrodes ANC may include titanium (Ti), titanium nitride (TiN), indium tin oxide (ITO), or indium zinc oxide (IZO), but embodiments of the present disclosure are limited thereto.

A plurality of reflective electrodes RL may be respectively arranged on the plurality of connection electrodes ANC. Each of the plurality of reflective electrodes RL may be arranged on the connection electrode ANC corresponding thereto. The plurality of reflective electrodes RL may be formed of any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one of them. For example, in one or more embodiments, each of the plurality of reflective electrodes RL may include aluminum (Al) having high reflectivity.

A plurality of optical auxiliary films OAL may be respectively arranged on the plurality of reflective electrodes RL. Each of the plurality of optical auxiliary films OAL may be arranged on the reflective electrode RL corresponding thereto. In one or more embodiments, the plurality of optical auxiliary films OAL may be formed of a silicon oxide (SiOₓ)-based inorganic film, but embodiments of the present disclosure are not limited thereto.

In each of the first emission area EA1 and the third emission area EA3, a step layer STPL may be arranged on the reflective electrode RL, and the optical auxiliary film OAL may be arranged on the step layer STPL. In the second emission area EA2, only the optical auxiliary film OAL may be arranged on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in each of the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be arranged on the optical auxiliary film OAL corresponding thereto. Because the connection electrode ANC, the reflective electrode RL, and the optical auxiliary layer OAL are sequentially stacked, the first electrode AND of each of the light emitting elements LE may be arranged on a top surface and a side surface of the optical auxiliary layer OAL, a side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. In one or more embodiments, the thickness of the first portion AA1 and the thickness of the second portion AA2 of the ninth interlayer insulating film INS9 may be substantially the same.

In one or more embodiments, the thickness of the first portion AA1 of the ninth interlayer insulating film INS9 may be greater than the thickness of the second portion AA2 thereof. In these embodiments, a side surface of the first portion AA1 of the ninth interlayer insulating film INS9 may be exposed, and the first electrode AND of each of the light emitting elements LE may be arranged on the exposed side surface of the first portion AA1 of the ninth interlayer insulating film INS9.

The first electrode AND of each of the light emitting elements LE may be formed of any one selected from among copper (Cu), aluminum (Al), tungsten (W), molybdenum (Mo), chromium (Cr), gold (Au), titanium (Ti), nickel (Ni), and neodymium (Nd), an alloy or a compound including any one of them, or a transparent conductive oxide. For example, in one or more embodiments, the first electrode AND of each of the light emitting elements LE may include titanium (Ti), titanium nitride (TiN), indium tin oxide (ITO), or indium zinc oxide (IZO), but embodiments of the present disclosure are limited thereto.

The pixel defining film PDL may be arranged on a part of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be arranged on the first electrode AND of each of the light emitting elements LE. For example, the first pixel defining film PDL1 may cover a part of a top surface of the first electrode AND arranged on the optical auxiliary film OAL. Further, the first pixel defining film PDL1 may cover the first electrode AND arranged on the side surface of the connection electrode ANC, the side surface of the reflective electrode RL, and the side surface of the optical auxiliary film OAL. The first pixel defining film PDL1 may be arranged on a top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be arranged on the first pixel defining film PDL1 covering the first electrode AND arranged on the side surface of the connection electrode ANC, the side surface of the reflective electrode RL, and the side surface of the optical auxiliary film OAL. The planarization film PNS may be arranged on the first pixel defining film PDL1 arranged on the second portion AA2 of the ninth interlayer insulating film INS9.

The planarization film PNS may be arranged between the connection electrodes ANC adjacent in the first direction DR1 or the second direction DR2. The planarization film PNS may be arranged between the reflective electrodes RL adjacent in the first direction DR1 or the second direction DR2. The planarization film PNS may be arranged between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the height of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover a top surface of the first pixel defining film PDL1 arranged on the top surface of the first electrode AND arranged in the second emission area EA2.

In contrast, a top surface of the planarization film PNS may be flatly connected to the top surface of the first pixel defining film PDL1 arranged on the top surface of the first electrode AND arranged in the first emission area EA1 and the third emission area EA3. For example, the planarization film PNS may not cover the top surface of the first pixel defining film PDL1 arranged on the top surface of the first electrode AND arranged in each of the first emission area EA1 and the third emission area EA3.

The second pixel defining film PDL2 may be arranged on the first pixel defining film PDL1 and the planarization film PNS, the third pixel defining film PDL3 may be arranged on the second pixel defining film PDL2, and the fourth pixel defining film PDL4 may be arranged on the third pixel defining film PDL3. In one or more embodiments, the first pixel defining film PDL1 and the third pixel defining film PDL3 may each be formed of a silicon nitride (SiNₓ)-based inorganic film, whereas the second pixel defining film PDL2, the fourth pixel defining film PDL4, and the planarization film PNS may each be formed of a silicon oxide (SiOₓ)-based inorganic film. The first pixel defining film PDL1 is formed of a material different from that of the planarization film PNS, and thus may serve as a stopper in a chemical mechanical polishing process for the planarization film PNS.

When the planarization film PNS and the second pixel defining film PDL2 are both (e.g., simultaneously) formed as a silicon oxide (SiOₓ)-based inorganic film, the planarization film PNS and the second pixel defining film PDL2 may be formed as a single film.

Because a length of the third pixel defining film PDL3 in one direction is less than a length of the fourth pixel defining film PDL4 in the one direction, a bottom surface of the fourth pixel defining film PDL4 may be exposed without being covered by the third pixel defining film PDL3. For example, the third pixel defining film PDL3 and the fourth pixel defining film PDL4 may have an eaves-shaped or mushroom-shaped cross-sectional structure.

The light emitting stack IL may be arranged on the first electrode AND and the pixel defining film PDL. The light emitting stack IL may include the first stack layer IL1 and the second stack layer IL2 that emit different lights. When the light emitting stack IL has a two-tandem structure, one selected from among the first stack layer IL1 and the second stack layer IL2 may be to emit light that includes the wavelength range of any one selected from among the first light, the second light, and the third light, and the other may be to emit light that includes the wavelength ranges of the other two lights. For example, in one or more embodiments, the first stack layer IL1 may be to emit light that includes the wavelength range of the first light and the wavelength range of the third light, and the second stack layer IL2 may be to emit light that includes the wavelength range of the second light. Here, the first light may be light of a blue wavelength band, the second light may be light of a green wavelength band, and the third light may be light of a red wavelength band.

A charge generation layer for supplying charges (e.g., holes) to the second stack layer IL2 and supplying electrons to the first stack layer IL1 may be arranged between the first stack layer IL1 and the second stack layer IL2. The charge generation layer may include an N-type (kind) charge generation layer that supplies electrons to the first stack layer IL1 and a P-type (kind) charge generation layer that supplies holes to the second stack layer IL2. The N-type (kind) charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this regard, the first hole transport layer of the first stack layer IL1, and the charge generation layer arranged between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it may prevent or reduce a leakage current from flowing through the first hole transport layer of the first stack layer IL1, the second hole transport layer of the second stack layer IL2, and the charge generation layer between the adjacent emission areas EA1, EA2, and EA3. Accordingly, it may prevent or reduce the light emitting stack IL in the adjacent emission areas EA1, EA2, and EA3 from emitting light other than the originally intended light due to the influence of the above current.

Although FIG. 10 illustrates a two-tandem structure in which the light emitting stack IL includes two stack layers IL1 and IL2, embodiments of the present disclosure are not limited thereto. For example, in one or more embodiments, the light emitting stack IL may have a three-tandem structure including three stack layers as shown in FIG. 9. In these embodiments, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. In one or more embodiments, as shown in FIG. 9, the trench TRC penetrating the first pixel defining film PDL1, the planarization film PNS, the second pixel defining film PDL2, and the third pixel defining film PDL3 may be added. In these embodiments, the trench TRC may penetrate at least a part of the ninth interlayer insulating film INS9, but embodiments of the present disclosure are not limited thereto.

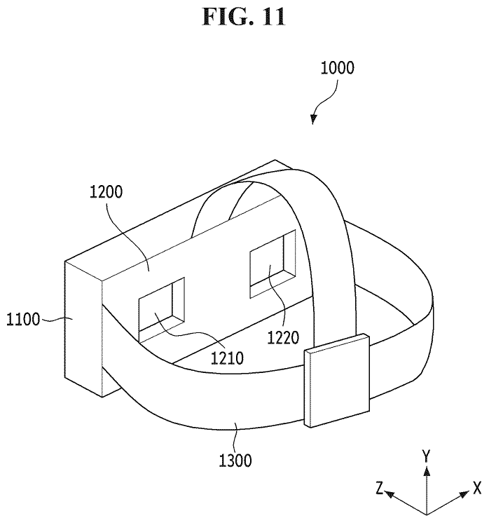

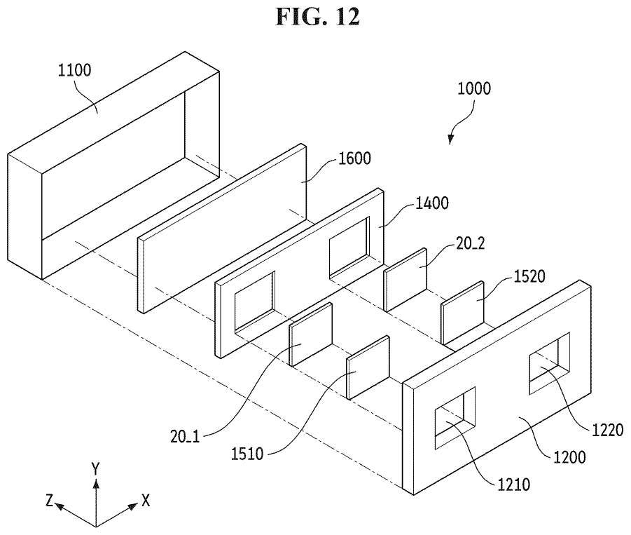

FIG. 11 is a schematic perspective view illustrating one example of a head mounted display according to one or more embodiments of the present disclosure. FIG. 12 is a schematic exploded perspective view illustrating the head mounted display shown in FIG. 11 according to one or more embodiments.

Referring to FIG. 11 and FIG. 12, a head mounted display 1000 according to one or more embodiments includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to a user's left eye, and the second display device 20_2 provides an image to a user's right eye. Because each of the first display device 20_1 and the second display device 20_2 is substantially the same as the display device 20 described in conjunction with FIGS. 3 to 10, the description of the first display device 20_1 and the second display device 20_2 will not be provided.

The first optical member 1510 may be arranged between the first display device 20_1 and the first eyepiece 1210. The second optical member 1520 may be arranged between the second display device 20_2 and the second eyepiece 1220. Each of the first optical member 1510 and the second optical member 1520 may include at least one convex lens.

The middle frame 1400 may be arranged between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be arranged between the middle frame 1400 and the display device housing 1100. The control circuit board 1600 may be connected to the first display device 20_1 and the second display device 20_2 through a connector. The control circuit board 1600 may convert an image source inputted from the outside into the digital video data DATA, and transmit the digital video data DATA to the first display device 20_1 and the second display device 20_2 through the connector.

In one or more embodiments, the control circuit board 1600 may be to transmit the digital video data DATA corresponding to a left-eye image improved or optimized for the user's left eye to the first display device 20_1, and may be to transmit the digital video data DATA corresponding to a right-eye image improved or optimized for the user's right eye to the second display device 20_2. In one or more embodiments, the control circuit board 1600 may be to transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye looks and the second eyepiece 1220 at which the user's right eye looks. FIG. 11 and FIG. 12 illustrate that the first eyepiece 1210 and the second eyepiece 1220 are arranged separately, but embodiments of the present disclosure is not limited thereto. In one or more embodiments, the first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

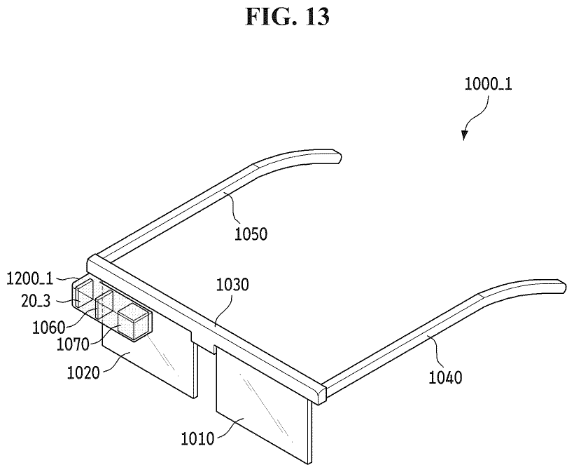

The head mounted band 1300 serves to secure the display device housing 1100 to the user's head such that the first eyepiece 1210 and the second eyepiece 1220 of the housing cover 1200 remain located on the user's left and right eyes, respectively. In one or more embodiments, when the display device housing 1200 is implemented to be lightweight and compact, the head mounted display 1000 may be provided with, as shown in FIG. 13, an eyeglass frame instead of the head mounted band 1300.

FIG. 13 is a schematic perspective view illustrating another example of a head mounted display according to one or more embodiments of the present disclosure.

Referring to FIG. 13, a head mounted display 1000_1 according to one or more embodiments may be an eyeglasses-type (kind) display device in which a display device housing 1200_1 is implemented in a lightweight and compact manner. The head mounted display 1000_1 according to one or more embodiments may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. An image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 13 illustrates that the display device housing 1200_1 is arranged at the right end of the support frame 1030, but embodiments of the present disclosure are not limited thereto. For example, in one or more embodiments, the display device housing 1200_1 may be arranged at the left end of the support frame 1030, and in these embodiments, the image of the display device 20_3 may be provided to the user's left eye. In one or more embodiments, the display device housing 1200_1 may be arranged at both (e.g., simultaneously) the left and right ends of the support frame 1030, and in these embodiments, the user may view the image displayed on the display device 20_3 through both (e.g., simultaneously) the left and right eyes.

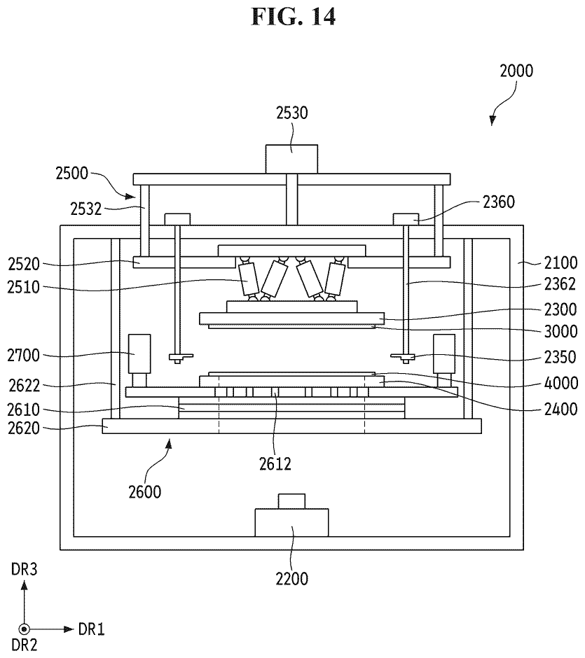

FIG. 14 is a schematic diagram illustrating a deposition mask and a deposition apparatus including the deposition mask according to one or more embodiments of the present disclosure.

Referring to FIG. 14, a deposition apparatus 2000 according to one or more embodiments may be used to form a deposition material layer on a substrate. For example, the deposition apparatus 2000 according to one or more embodiments may be used to form light emitting layers on a backplane substrate 3000 (or display substrate) in a manufacturing process of the display panel 100 (see FIG. 3). For example, as illustrated in FIG. 9, the semiconductor backplane SBP and the light emitting element backplane EBP may be arranged on the backplane substrate 3000, and the reflective electrodes RL and the insulating films INS10 and INS11 may be arranged on the light emitting element backplane EBP. Electrode patterns, e.g., the first electrodes AND functioning as anode electrodes and the pixel defining film PDL having openings that expose the first electrodes AND may be arranged on the insulating film INS11, and the first electrodes AND may be electrically connected to the reflective electrodes RL through the vias VA10. For example, in one or more embodiments, the deposition apparatus 2000 may form first light emitting layers on the first electrodes AND of the first emission areas EA1. The deposition apparatus 2000 may form second light emitting layers on the first electrodes AND of the second emission areas EA1. Additionally, the deposition apparatus 2000 may form third light emitting layers on the first electrodes AND of the third emission areas EA3.

The deposition apparatus 2000 may include a deposition source 2200 for providing a vapor deposition material on the backplane substrate 3000, a substrate chuck 2300 for supporting the backplane substrate 3000 so as to face the deposition source 2200, and a mask chuck 2400 arranged between the deposition source 2200 and the substrate chuck 2300 to support a deposition mask 4000 so as to face the backplane substrate 3000. The deposition source 2200, the substrate chuck 2300, and the mask chuck 2400 may be arranged in a process chamber (or an evaporation chamber) 2100.

The process chamber 2100 may have an internal space, and a deposition process for forming a deposition material layer on the backplane substrate 3000 may be performed in the internal space of the process chamber 2100. The process chamber 2100 may be connected to a vacuum pump, and a vacuum atmosphere may be created in the internal space of the process chamber 2100 by the vacuum pump. An opening for loading/unloading of the backplane substrate 3000 and the deposition mask 4000 may be provided on a (e.g., one) wall of the process chamber 2100, and the opening may be opened and closed by a gate valve.

The deposition source 2200 may be arranged in the process chamber 2100, and a deposition material may be stored in the deposition source 2200. The deposition source 2200 may evaporate a deposition material such as an organic material, an inorganic material, a conductive material, and/or the like toward the backplane substrate 3000, and the evaporated deposition material may be deposited on the backplane substrate 3000 through the deposition mask 4000. For example, the deposition source 2200 may evaporate an organic light emitting material for forming light emitting layers on the backplane substrate 3000, and may be provided with a heater for evaporating the organic light emitting material. The evaporated organic light emitting material may be deposited on electrode patterns on the backplane substrate 3000 through the deposition mask 4000, thereby forming light emitting layers on the electrode patterns of the backplane substrate 3000. As shown in FIG. 14, in one or more embodiments, the deposition source 2200 may be arranged on a central portion of the bottom surface of the process chamber 2100, but, in one or more embodiments, the deposition source 2200 may be configured to move horizontally by a separate driver.

The substrate chuck 2300 may be arranged above the deposition source 2200 and may support the backplane substrate 3000 such that the backplane substrate 3000 faces the deposition source 2200. For example, in one or more embodiments, the substrate chuck 2300 may be an electrostatic chuck that holds the rear surface of the backplane substrate 3000 using an electrostatic force. For example, the electrode patterns, e.g., first electrodes AND, may be arranged on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2350 for loading the backplane substrate 3000 onto the substrate chuck 2300 may be arranged in the process chamber 2100. The lift fingers 2350 may be arranged around the substrate chuck 2300 and the mask chuck 2400, and may be respectively moved vertically by finger drivers 2360. For example, three or four lift fingers 2350 may be arranged around the substrate chuck 2300 and the mask chuck 2400, and may be moved in the third direction DR3 by the finger drivers 2350.

The backplane substrate 3000 may be loaded into the process chamber 2100 by a transfer robot, and may be transferred from the transfer robot onto the lift fingers 2350 under the substrate chuck 2300. In this regard, the rear surface of the backplane substrate 3000 may face the bottom surface of the substrate chuck 2300, and the lift fingers 2350 may support front edge portions of the backplane substrate 3000. The finger drivers 2360 may raise the lift fingers 2350 such that the backplane substrate 3000 becomes adjacent to the bottom surface of the substrate chuck 2300, and the rear surface of the backplane substrate 3000 may be held on the bottom surface of the substrate chuck 2300 by an electrostatic force.

The finger drivers 2360 may be arranged on an upper lid of the process chamber 2100 and may be respectively connected to the lift fingers 2350 through driving shafts 2362 that extend vertically through the upper lid of the process chamber 2100. The finger drivers 2360 may vertically move the lift fingers 2350 to load or unload the backplane substrate 3000. In addition, the finger drivers 2360 may rotate the lift fingers 2350 with respect to their corresponding driving shafts 2362. For example, the finger drivers 2360 may rotate the lift fingers 2350 such that the ends of the lift fingers 2350 do not overlap the substrate chuck 2300 and the mask chuck 2400, thereby enabling vertical movement of the lift fingers 2350. In addition, the finger drivers 2360 may rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot, and may be transferred onto the lift fingers 2350 above the mask chuck 2400. The edge portions of the deposition mask 4000 may be placed on the ends of the lift fingers 2350, and the finger drivers 2360 may lower the lift fingers 2350 to load the deposition mask 4000 onto the mask chuck 2300. In this regard, recesses into which ends of lift fingers 2350 are inserted may be provided at the edge portions of the mask chuck 2400, and the finger drivers 2360 may rotate the lift fingers 2350 such that the lift fingers 2350 do not overlap the mask chuck 2400 after the deposition mask 4000 is loaded on the mask chuck 2400.

The mask chuck 2400 may support the edge portion of the deposition mask 4000. For example, in one or more embodiments, the mask chuck 2400 may be an electrostatic chuck configured to hold the edge portion of the deposition mask 4000 using an electrostatic force. In one or more embodiments, the mask chuck 2400 may have a circular opening to expose the deposition mask 4000 toward the deposition source 2200. For example, the mask chuck 2400 may have a disk shape or a quadrilateral plate shape (e.g., in a form of plate) with a circular opening.

The deposition apparatus 2000 may include a chuck driver for adjusting the position and posture of the backplane substrate 3000 and the deposition mask 4000. For example, the deposition apparatus 2000 may include a substrate chuck driver 2500 for moving the substrate chuck 2300 and a mask chuck driver 2600 for moving the mask chuck 2400.

The substrate chuck driver 2500 may move the substrate chuck 2300 in the first direction DR1, the second direction DR2, and the third direction DR3 to adjust the position of the backplane substrate 3000. In this regard, the first direction DR1 may be a first horizontal direction, the second direction DR2 may be a second horizontal direction perpendicular to the first direction DR1, and the third direction DR3 may be the vertical direction. For example, the first direction DR1, the second direction DR2, and the third direction DR3 may be an X-axis direction, a Y-axis direction, and a Z-axis direction, respectively.

The substrate chuck driver 2500 may rotate the substrate chuck 2300 around the Z-axis to adjust the azimuth of the backplane substrate 3000, that is, the angle at which the backplane substrate 3000 is held on the bottom surface of the substrate chuck 2300. Further, the substrate chuck driver 2500 may rotate the substrate chuck 2300 around the X-axis, and may also rotate the substrate chuck 2300 around the Y-axis in order to adjust the inclination of the backplane substrate 3000. For example, the substrate chuck driver 2500 may include a hexapod actuator 2510 that provides a motion of six degrees of freedom (X, Y, Z, θx, θy, and θz).

The substrate chuck driver 2500 may include a substrate stage 2520 to which the hexapod actuator 2510 is mounted, and a second actuator 2530 connected to the substrate stage 2520. The substrate stage 2520 may be arranged horizontally in the process chamber 2100, and the second actuator 2530 may be arranged above the process chamber 2100. The second actuator 2530 may be connected to the substrate stage 2520 by a plurality of driving shafts 2532 extending in the third direction DR3, i.e., the vertical direction (Z-axis direction) through the upper lid of the process chamber 2100, and may move the substrate stage 2520 in the central axis direction of the hexapod actuator 2510, i.e., the vertical direction. For example, the second actuator 2530 may be configured using a brushless DC motor, a linear motor, a direct drive (DD) motor, and/or the like, and may adjust a height of the substrate chuck 2300 for loading or unloading the backplane substrate 3000.

The hexapod actuator 2510 may include a first platform connected to the substrate chuck 2300, a second platform mounted to the substrate stage 2520, and six sub-actuators arranged between the first platform and the second platform. For example, the six sub-actuators may each be configured using a brushless DC motor, a voice coil linear motor, a step motor, a direct drive (DD) motor, a servo motor, and/or the like, and may move and rotate the first platform to adjust the horizontal position, vertical position, azimuth, and inclination of the backplane substrate 3000.

The mask chuck driver 2600 may move and rotate the mask chuck 2400 to adjust the horizontal position of the deposition mask 4000 and the azimuth angle of the deposition mask 4000, that is, the angle at which the deposition mask 4000 is placed on the mask chuck 2400. The mask chuck driver 2600 may move the mask chuck 2400 in a direction parallel to the deposition mask 4000 and rotate the mask chuck 2400 with respect to a central axis of the mask chuck 2400. For example, the mask chuck driver 2600 may move the mask chuck 2400 in the first direction DR1 (X-axis) and the second direction DR2 (Y-axis), and may rotate the mask chuck 2400 with respect to the third direction DR3 (Z-axis).

The mask chuck driver 2600 may include, e.g., a piezo actuator 2610 that provides a motion of three degrees of freedom (X, Y, and θz). The piezo actuator 2610 may have an opening communicating with the circular opening of the mask chuck 2400. The mask chuck 2400 may be spaced upward from the piezo actuator 2610 by a selected distance. For example, a plurality of support members 2612 may be arranged on the piezo actuator 2610, and the mask chuck 2400 may be arranged on the plurality of support members 2612.

The mask chuck driver 2600 may include a mask stage 2620 that is horizontally arranged in the process chamber 2100 and supports the piezo actuator 2610. For example, the mask stage 2620 may have an opening that communicates with the opening of the piezo actuator 2610 and may be supported by a plurality of posts 2622 that are connected to the upper lid of the process chamber 2100.

After the backplane substrate 3000 and the deposition mask 4000 are loaded onto the substrate chuck 2300 and the mask chuck 2400, respectively, the second actuator 2530 may lower the substrate chuck 2300 such that the backplane substrate 3000 is brought adjacent to the deposition mask 4000. The hexapod actuator 2510 may adjust a gap between the backplane substrate 3000 and the deposition mask 4000, and may adjust the inclination of the substrate chuck 2300 to adjust the parallelism between the substrate chuck 2300 and the mask chuck 2400. For example, in one or more embodiments, a plurality of gap sensors for measuring the gap between the substrate chuck 2300 and the mask chuck 2400 may be mounted at the substrate chuck 2300, and the hexapod actuator 2510 may adjust the parallelism between the substrate chuck 2300 and the mask chuck 2400 based on the measured values of the gap sensors.

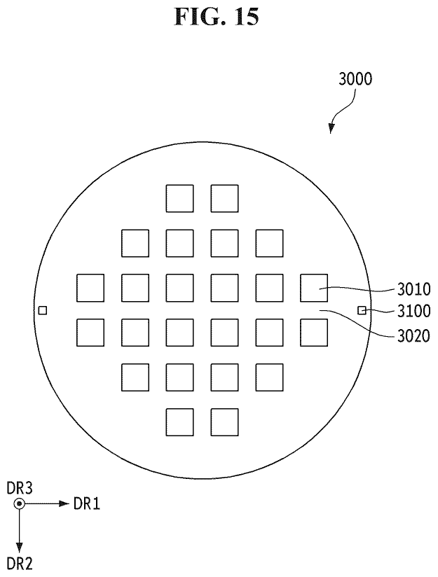

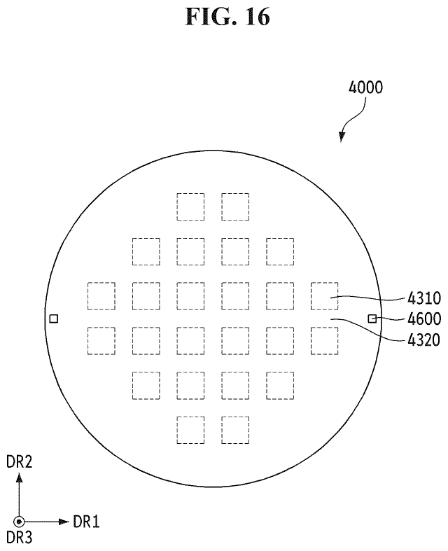

The deposition apparatus 2000 may include cameras 2700 for acquiring positional information of the backplane substrate 3000 and the deposition mask 4000 for alignment between the backplane substrate 3000 and the deposition mask 4000. For example, substrate alignment keys 3100 (see FIG. 15) may be arranged on the edge portions of the backplane substrate 3000, and mask alignment keys 4600 (see FIG. 16) may be arranged on the edge portions of the deposition mask 4000. The deposition apparatus 2000 may include the cameras 2700 for detecting the substrate alignment keys 3100 and the mask alignment keys 4600, and the substrate chuck driver 2500 or the mask chuck driver 2600 may align the backplane substrate 3000 and the deposition mask 4000 with each other based on the positional information of the substrate alignment keys 3100 and the mask alignment keys 4600 obtained by the cameras 2700.

As described above, after the parallelism adjustment between the substrate chuck 2300 and the mask chuck 2400 and the positional alignment between the backplane substrate 3000 and the deposition mask 4000 are performed, the backplane substrate 3000 may be positioned on the deposition mask 4000. For example, the hexapod actuator 2510 may adjust the height of the substrate chuck 2300 such that the gap between the backplane substrate 3000 and the deposition mask 4000 becomes a selected or set gap, e.g., a gap of several micrometers (μm). In one or more embodiments, the hexapod actuator 2510 may adjust the height of the substrate chuck 2300 such that the backplane substrate 3000 is brought into contact with the deposition mask 4000.

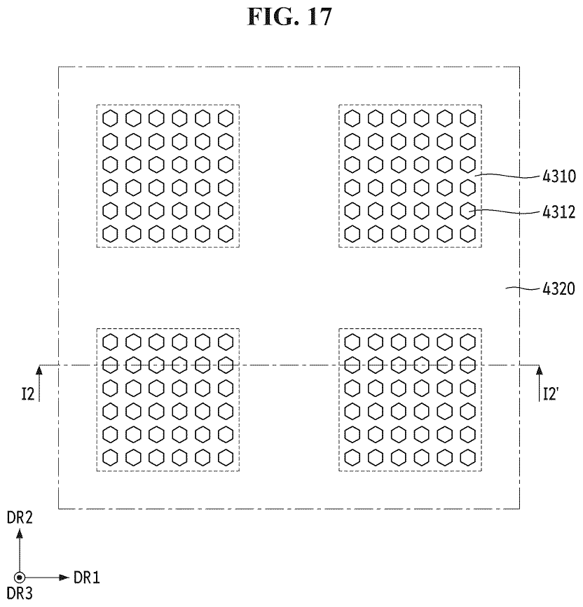

After the backplane substrate 3000 is positioned on the deposition mask 4000, the deposition source 2200 may provide a vapor deposition material onto the backplane substrate 3000 through the deposition mask 4000, thereby forming a deposition material layer on the backplane substrate 3000. For example, in one or more embodiments, the deposition source 2200 may evaporate an organic material for forming light emitting layers on the backplane substrate 3000, and the evaporated organic material may be deposited on the electrode patterns of the backplane substrate 3000 through the pixel openings 4312 (see FIG. 17) of the deposition mask 4000.

FIG. 15 is a schematic bottom view illustrating the backplane substrate shown in FIG. 14 according to one or more embodiments of the present disclosure.

Referring to FIG. 15, the backplane substrate 3000 may include a plurality of display cell regions 3010 and a scribe lane region 3020 arranged between the display cell regions 3010. In one or more embodiments, the display cell regions 3010 may be arranged in a matrix form along the first direction DR1 and the second direction DR2 as illustrated in FIG. 15, and may be individualized into the display panels 100 (see FIG. 3) by a dicing process after the display manufacturing process is completed. For example, the first direction DR1 may be a first horizontal direction, and the second direction DR2 may be a second horizontal direction normal (e.g., perpendicular) to the first direction DR1. In one or more embodiments, each of the display cell regions 3010 may have, for example, a quadrilateral shape as shown in the drawing.

For example, each of the display cell regions 3010 may include the semiconductor backplane SBP, the light emitting element backplane EBP arranged on the semiconductor backplane SBP, the reflective electrodes RL arranged on the light emitting element backplane EBP, and the insulating films INS10 and INS11 as shown in FIG. 9. In addition, each of the display cell regions 3010 may include a plurality of electrode patterns, for example, the plurality of first electrodes AND arranged on the insulating film INS11, and the first electrodes AND may be connected to the reflective electrodes RL through the plurality of vias VA10, as shown in FIG. 9. In this regard, the electrode patterns of the display cell regions 3010 may be arranged on the front surface of the backplane substrate 3000, and the substrate chuck 2300 may hold the rear surface of the backplane substrate 3000 such that the electrode patterns of the display cell regions 3010 face downward, i.e., face the deposition source 2200.

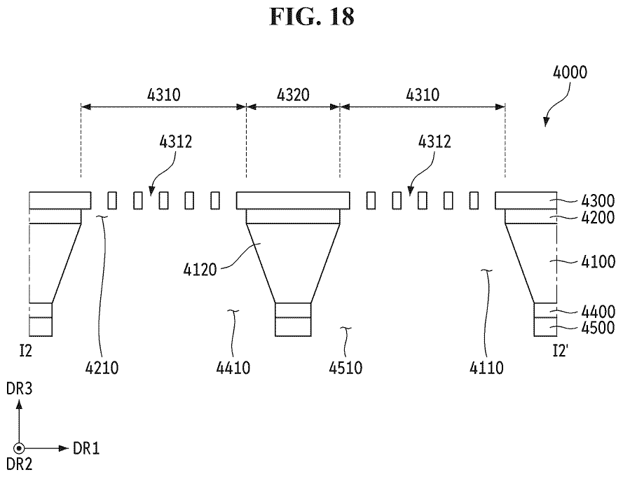

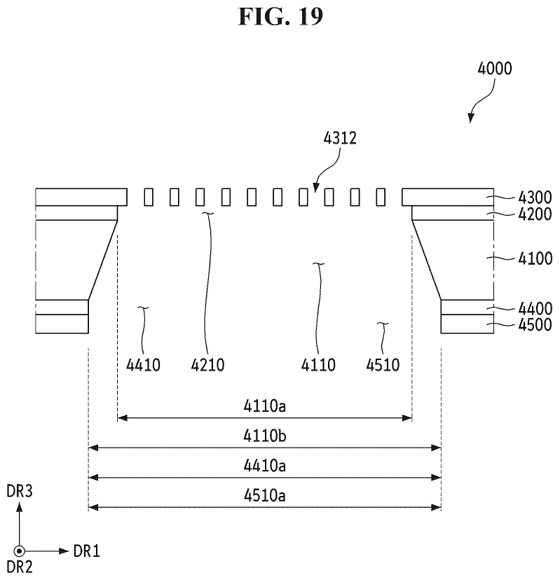

FIG. 16 is a schematic plan view illustrating the deposition mask shown in FIG. 14 according to one or more embodiments of the present disclosure. FIG. 17 is a schematic enlarged plan view illustrating the mask cell regions shown in FIG. 16 according to one or more embodiments. FIG. 18 is a schematic cross-sectional view taken along the line I2-I2′ shown in FIG. 17 according to one or more embodiments. FIG. 19 is an enlarged cross-sectional view schematically illustrating the cell opening, intermediate opening, and rear opening shown in FIG. 18 according to one or more embodiments.

Referring to FIGS. 16 to 19, the deposition mask 4000 may include mask cell regions 4310 respectively corresponding to the display cell regions 3010 of the backplane substrate 3000, and a grid region 4320 corresponding to the scribe lane region 3020 of the backplane substrate 3000. Each of the mask cell regions 4310 may have a plurality of pixel openings 4312 exposing the first electrodes AND of the backplane substrate 3000 in a deposition process. For example, the deposition mask 4000 may include a mask substrate 4100, a buffer inorganic film 4200 arranged on the mask substrate 4100, and a membrane 4300 arranged on the buffer inorganic film 4200. In this regard, the membrane 4300 may include the plurality of mask cell regions 4310 and the grid region 4320 around (e.g., surrounding) the mask cell regions 4310, and each of the mask cell regions 4310 may have the plurality of pixel openings 4312.

The mask substrate 4100 may have cell openings 4110 respectively corresponding to the mask cell regions 4310, and may include a rib region 4120 defining the cell openings 4110. The buffer inorganic film 4200 may have buffer openings 4210 respectively arranged on the cell openings 4110. In this regard, the mask cell regions 4310 of the membrane 4300 may be respectively arranged above the buffer openings 4210, and the pixel openings 4312 of the membrane 4300 may communicate with the cell openings 4110 through the buffer openings 4210.

According to one or more embodiments, the mask cell regions 4310 of the membrane 4300 may be exposed toward the deposition source 2200 through the cell openings 4110 of the mask substrate 4100 and the buffer openings 4210 of the buffer inorganic film 4200, and the pixel openings 4312 may be formed to penetrate the mask cell regions 4310. In these embodiments, while performing the deposition process, the vapor deposition material provided from the deposition source 2200 may be deposited on the first electrodes AND of the backplane substrate 3000 through the cell openings 4110, the buffer openings 4210, and the pixel openings 4312.

As shown in FIG. 16, in one or more embodiments, the mask cell regions 4310 may be arranged in a matrix form along the first direction DR1 and the second direction DR2. For example, the first direction DR1 may be the first horizontal direction, and the second direction DR2 may be the second horizontal direction normal (e.g., perpendicular) to the first direction DR1. In one or more embodiments, the mask cell regions 4310 may have, for example, a quadrilateral shape as shown in the drawing, and the pixel openings 4312 may be arranged to correspond to the first electrodes AND of any of the first emission areas EA1, the second emission areas EA2, and the third emission areas EA3.

The mask substrate 4100 may include single crystal silicon. For example, in one or more embodiments, a single crystal silicon substrate having a thickness in the range of about 700 μm to about 800 μm, e.g., about 775 μm, may be used as the mask substrate 4100.

The buffer inorganic film 4200 and the membrane 4300 may be arranged on a front surface of the mask substrate 4100, and an intermediate inorganic film 4400 and a rear inorganic film 4500 may be arranged on a rear surface of the mask substrate 4100. For example, the intermediate inorganic film 4400 may be arranged on the rear surface of the mask substrate 4100, and the rear inorganic film 4500 may be arranged on the intermediate inorganic film 4400.

The intermediate inorganic film 4400 and the rear inorganic film 4500 may have intermediate openings 4410 and rear openings 4510 communicating with the cell openings 4110, respectively, and the rear inorganic film 4500 may function as an etching mask in an etching process for forming the cell openings 4110. In this regard, the mask cell regions 4310 may be exposed toward the deposition source 2200 through the buffer openings 4210, the cell openings 4110, the intermediate openings 4410, and the rear openings 4510. In addition, the vapor deposition material provided from the deposition source 2200 during the deposition process may be deposited on the first electrodes AND of the backplane substrate 3000 through the rear openings 4510, the intermediate openings 4410, the cell openings 4110, the buffer openings 4210, and the pixel openings 4312.

According to one or more embodiments, the membrane 4300 may include a material having etching selectivity with respect to the buffer inorganic film 4200 and the mask substrate 4100. For example, in one or more embodiments, the buffer inorganic film 4200 may include silicon oxide (SiOₓ), and the membrane 4300 may include silicon nitride (SiNₓ). According to one or more embodiments, the buffer inorganic film 4200 may include a same material as the intermediate inorganic film 4400, and the membrane 4300 may include a same material as the rear inorganic film 4500. For example, the buffer inorganic film 4200 and the intermediate inorganic film 4400 may be formed concurrently (e.g., simultaneously) by a thermal oxidation process, and the membrane 4300 and the rear inorganic film 4500 may be formed concurrently (e.g., simultaneously) by a chemical vapor deposition (CVD) process.

The pixel openings 4312 of the membrane 4300 may be formed by an anisotropic etching process, e.g., a reactive ion etching (RIE) process. For example, in one or more embodiments, after forming, on the membrane 4300, a photoresist pattern exposing portions where the pixel openings 4312 are to be formed, an RIE process using the photoresist pattern as an etching mask may be performed to form the pixel openings 4312 that expose the buffer inorganic film 4200. In this regard, the pixel openings 4312 may be formed to penetrate the membrane 4300, and the buffer inorganic film 4200 may function as an etch stop film in the RIE process.

The intermediate openings 4410 and the rear openings 4510 may be formed by an anisotropic etching process, e.g., an RIE process. For example, in one or more embodiments, after forming, on the rear inorganic film 4500, a photoresist pattern that exposes portions where the rear openings 4510 are to be formed, an RIE process that uses the photoresist pattern as an etching mask may be performed to form the intermediate openings 4410 and the rear openings 4510 that expose the rear surface of the mask substrate 4100.

The cell openings 4110 of the mask substrate 4100 may be formed to expose the buffer inorganic film 4200 by an anisotropic etching process using the intermediate inorganic film 4400 and the rear inorganic film 4500 as an etching mask. For example, in one or more embodiments, a single crystal silicon substrate may be used as the mask substrate 4100, and the cell openings 4110 may be formed by a wet etching process using an etchant such as a tetramethylammonium hydroxide (TMAH) solution, or a potassium hydroxide (KOH) solution. In this regard, the <100> crystal direction of the single crystal silicon substrate used as the mask substrate 4100 may be the third direction DR3, and accordingly, the cell openings 4110 may have a width that gradually decreases from the rear surface of the mask substrate 4100 toward the front surface of the mask substrate 4100 through the wet etching process. For example, inner side surfaces of the cell openings 4110 may each have an inclination angle of about 54.7° with respect to the rear surface of the mask substrate 4100.

The buffer openings 4210 of the buffer inorganic film 4200 may be formed by a wet etching process after forming the cell openings 4110 of the mask substrate 4100. For example, if (e.g., when) the buffer inorganic film 4200 includes silicon oxide (SiOₓ), the buffer openings 4210 may be formed by a wet etching process that uses an etchant such as buffered oxide etchant (BOE), diluted hydrofluoric acid (HF), and/or the like. As a result, the pixel openings 4312 of the membrane 4300 may communicate with the cell openings 4110 of the mask substrate 4100 through the buffer openings 4210 of the buffer inorganic film 4200.

While forming the cell openings 4110, the mask substrate 4100 may be etched in a <111> direction of the mask substrate 4100, i.e., in a direction perpendicular to the inner side surfaces of the cell openings 4110. Although not shown in the drawings, in the case of a typical deposition mask, undercut structures may be formed between the intermediate inorganic film and the cell openings while forming the cell openings. In addition, the intermediate inorganic film may be partially removed while forming the buffer openings, and accordingly, undercut structures may be formed between the rear inorganic film and the cell openings. The undercut structures may be structurally weak, and thus damage to the rear inorganic film may occur during the deposition process.

In addition, during the deposition process, the vapor deposition material may be deposited on the deposition mask 4000, and a deposition material layer formed on the deposition mask 4000 may be removed through a cleaning process. For example, the deposition material layer on the deposition mask 4000 may be removed by an ultrasonic cleaning process using an N-methyl-2-pyrrolidone (NMP) cleaning solution. Ultrasonic vibrations may be applied to the deposition mask 4000 during the ultrasonic cleaning process. In the case of a typical deposition mask, the rear inorganic film forming the undercut structures may be damaged by the ultrasonic vibrations, and particles may be generated from the rear inorganic film.

However, according to one or more embodiments of the present disclosure, the rear openings 4510 may each have the same width as their corresponding cell openings (e.g., each have the same width as the rear width of their corresponding cell openings 4110). That is, the rear openings 4510 may have the same width as the rear widths of their corresponding cell openings 4110. For example, as shown in FIG. 19, the cell openings 4110 may each have a front width 4110a adjacent to the membrane 4300 and a rear width 4110b adjacent to the rear inorganic film 4500, and a width 4510a of the rear openings 4510 may be the same as the rear width 4110b of their corresponding cell openings 4110. According to one or more embodiments, the intermediate openings 4410 of the intermediate inorganic film 4400 may each have a width 4410a that is the same as the rear width 4110b of their corresponding cell openings 4110. For example, the rear width 4110b of the cell openings 4110, the width 4410a of the intermediate openings 4410, and the width 4510a of the rear openings 4510 may all be the same.

According to one or more embodiments, the undercut structures may be removed from the deposition mask 4000. Therefore, damage to the rear inorganic film 4500 may be prevented or reduced during the deposition process or the ultrasonic cleaning process. In addition, the width 4410a of the intermediate openings 4410 and the width 4510a of the rear openings 4510 may be the same as the rear width 4110b of their corresponding cell openings 4110, and accordingly, the amount of deposition material blocked by the rear inorganic film 4500 during the deposition process may be reduced.

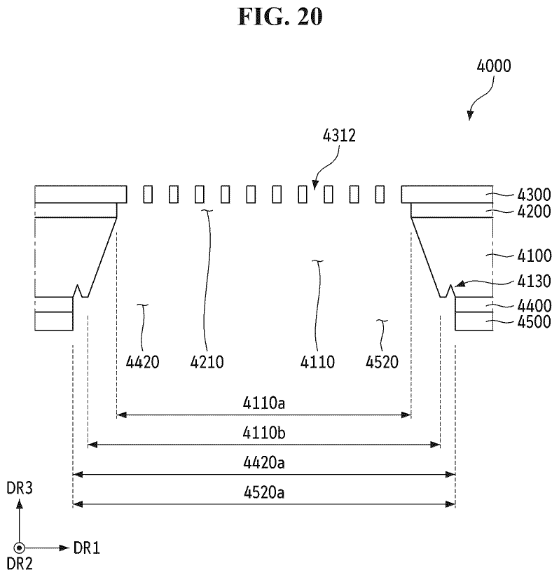

FIG. 20 is a schematic enlarged cross-sectional view illustrating another example of the intermediate opening and the rear opening shown in FIG. 19 according to one or more embodiments of the present disclosure.

Referring to FIG. 20, the intermediate inorganic film 4400 may have intermediate openings 4420 communicating with the cell openings 4110, and the rear inorganic film 4500 may have rear openings 4520 communicating with the intermediate openings 4420 and the cell openings 4110. According to one or more embodiments, the intermediate openings 4420 may each have a width 4420a greater than the width of their corresponding cell openings 4110. In addition, the rear openings 4520 may each have a width 4520a greater than the width of their corresponding cell openings 4110. For example, the width 4420a of the intermediate openings 4420 may be greater than the rear width 4110b of their corresponding cell openings 4110. In addition, the width 4520a of the rear openings 4520 may be greater than the rear width 4110b of their corresponding cell openings 4110.

According to one or more embodiments, the mask substrate 4100 may have ring-shaped grooves 4130 around (e.g., surrounding) the cell openings 4110. For example, the grooves 4130 may be formed to respectively surround the cell openings 4110 in rear portions of the mask substrate 4100. Each of the grooves 4130 may have inner side surfaces connected to each other, and the inner side surfaces of the grooves 4130 may have an inclination angle of about 54.7° with respect to the rear surface of the mask substrate 4100. In this regard, the grooves 4130 may be exposed through the intermediate openings 4420 and the rear openings 4520. In addition, the width 4420a of the intermediate openings 4420 may be equal to or greater than the width 4520a of their corresponding rear openings 4520.

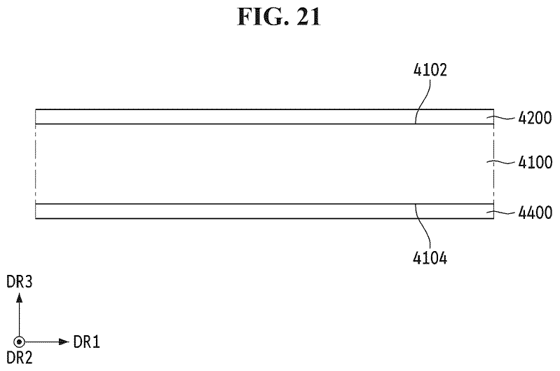

FIGS. 21 to 29 are schematic enlarged cross-sectional views illustrating a method of manufacturing a deposition mask according to one or more embodiments of the present disclosure.

Referring to FIG. 21, the buffer inorganic film 4200 may be formed on the mask substrate 4100. The mask substrate 4100 may include single crystal silicon. For example, in one or more embodiments, a single crystal silicon substrate having a thickness in the range of about 700 μm to about 800 μm, e.g., about 775 μm, may be used as the mask substrate 4100.

The buffer inorganic film 4200 may include, for example, silicon oxide (SiOₓ) and may be formed with a thickness of about 0.2 μm to about 2 μm on a front surface 4102 of the mask substrate 4100 through a thermal oxidation process. In addition, the intermediate inorganic film 4400 may be formed on a rear surface 4104 of the mask substrate 4100. According to one or more embodiments, the intermediate inorganic film 4400 may include silicon oxide (SiOₓ). For example, in one or more embodiments, the intermediate inorganic film 4400 may be formed concurrently (e.g., simultaneously) with the buffer inorganic film 4200 by a thermal oxidation process. In these embodiments, the intermediate inorganic film 4400 may include a same material as the buffer inorganic film 4200 and may have a same thickness as the buffer inorganic film 4200.

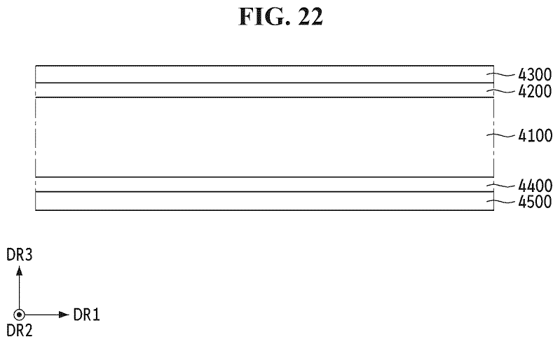

Referring to FIG. 22, the membrane 4300 may be formed on the buffer inorganic film 4200. For example, the membrane 4300 may contain silicon nitride (SiNₓ) and may be formed by a CVD process. For example, in one or more embodiments, a silicon source gas, such as monosilane (SiH₄), disilane (Si₂H₆), or dichlorosilane (DCS) (SiH₂Cl₂), and a nitrogen source gas, such as N₂ or NH₃, may be supplied onto the buffer inorganic film 4200, and the membrane 4300 may be formed with a thickness of about 0.3 μm to about 3 μm by a reaction between the silicon source gas and the nitrogen source gas.

The rear inorganic film 4500 may be formed on the intermediate inorganic film 4400. The rear inorganic film 4500 may include silicon nitride (SiNₓ) and may be formed by a CVD process. For example, in one or more embodiments, the membrane 4300 and the rear inorganic film 4500 may be formed concurrently (e.g., simultaneously) by a CVD process. In these embodiments, the rear inorganic film 4500 may include a same material as the membrane 4300 and may have a same thickness as the membrane 4300.

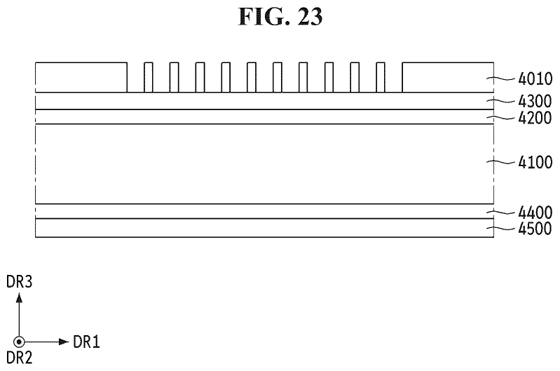

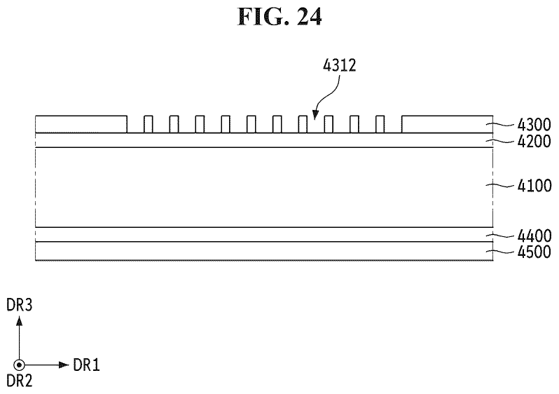

Referring to FIG. 23 and FIG. 24, the membrane 4300 may be patterned to form the pixel openings 4312. For example, the pixel openings 4312 may be formed by forming, on the membrane 4300, a first photoresist pattern 4010 that exposes the portions where the pixel openings 4312 are to be formed and then performing an anisotropic etching process, for example, an RIE process using the first photoresist pattern 4010 as an etching mask. In this regard, the pixel openings 4312 may be formed to expose the buffer inorganic film 4200, and the first photoresist pattern 4010 may be removed through an ashing and/or stripping process after forming the pixel openings 4312.

For example, if (e.g., when) the membrane 4300 includes silicon nitride (SiNₓ), the RIE process may be performed using a first reactive gas, such as CF₄, C₂F₄, C₂F₆, C₃F₆, C₃F₈, C₄F₆, C₄F₈, CH₃F, CH2F₂, C₂HF₅, CHF₃, NF₃, or SF₆, containing fluorine, a second reactive gas, such as O₂, NO, or NO₂, containing oxygen, and a sputtering gas, such as He, Ne, Ar, or Xe, until the buffer inorganic film 4200 is exposed. In this regard, the buffer inorganic film 4200 may function as an etch stop film in the RIE process.

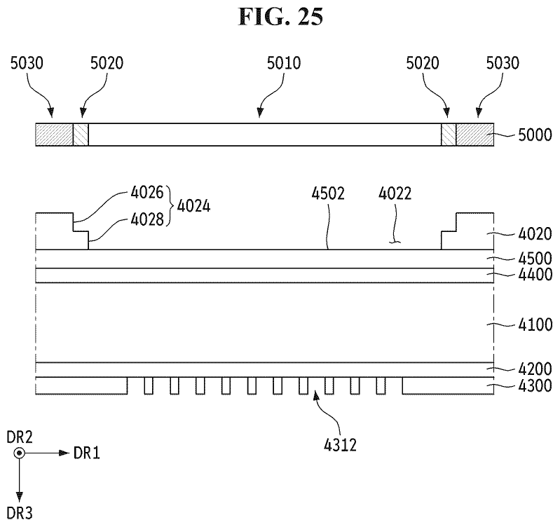

Referring to FIGS. 25 to 27, the rear inorganic film 4500 and the intermediate inorganic film 4400 may be patterned to form the rear openings 4510 and preliminary intermediate openings 4404. According to one or more embodiments, the rear openings 4510 may penetrate the rear inorganic film 4500, and the preliminary intermediate openings 4404 may penetrate the intermediate inorganic film 4400 to expose the rear portions of the mask substrate 4100. In addition, the preliminary intermediate openings 4404 may each have a smaller width than their corresponding rear openings 4510.

According to one or more embodiments, as shown in FIG. 25, a second photoresist pattern 4020 having pattern openings 4022 that expose portions of the rear inorganic film 4500 may be formed on the rear inorganic film 4500. For example, each of the pattern openings 4022 may have a ring-shaped stepped portion 4024, and may include a first opening 4026 corresponding to the rear opening 4510 and a second opening 4028 corresponding to the preliminary intermediate opening 4404. According to one or more embodiments, and the second opening 4028 may have a smaller width than the first opening 4026. For example, the first opening 4026 may have the same width as the rear opening 4510, and the second opening 4028 may have the same width as the preliminary intermediate opening 4404. In addition, for example, the first opening 4026 may have the same size and the same shape as the rear opening 4510, and the second opening 4028 may have the same size and the same shape as the preliminary intermediate opening 4404.

According to one or more embodiments, a thickness of the second photoresist pattern 4020 may be about 3 μm to about 7 μm, a thickness of a portion defining the second opening 4028 may be about 0.5 μm to about 2 μm, and a width of the portion defining the second opening 4028 may be about 30 μm to about 60 μm. For example, in one or more embodiments, the thickness of the second photoresist pattern 4020 may be about 5 μm, the thickness of the portion defining the second opening 4028 may be about 1 μm, and the width of the portion defining the second opening 4028 may be about 50 μm.

The pattern openings 4022 of the second photoresist pattern 4020 may be formed by a photolithography process that uses a halftone mask 5000. For example, in one or more embodiments, if (e.g., when) a positive photoresist layer is formed on the rear inorganic film 4500, the halftone mask 5000 may include transmissive regions 5010 corresponding to the second openings 4028, semi-transmissive regions 5020 having a ring shape that surrounds the transmissive regions 5010 and corresponding to the first openings 4026, and a blocking region 5030 around (e.g., surrounding) the semi-transmissive regions 5020. Light irradiated onto the halftone mask 5000 during an exposure process may be provided onto the photoresist layer through the transmissive regions 5010 and the semi-transmissive regions 5020. In this regard, the transmissive regions 5010 may be to transmit all light irradiated onto the transmissive regions 5010, and the semi-transmissive regions 5020 may be to transmit part of light irradiated onto the semi-transmissive regions 5020. For example, in one or more embodiments, each of the semi-transmissive regions 5020 may have a plurality of through holes for transmitting part of light.

After the exposure process, a developing process may be performed. During the developing process, portions of the photoresist layer exposed through the transmissive regions 5010 may all be removed to form the second openings 4028, and portions of the photoresist layer exposed through the semi-transmissive regions 5020 may be partially removed to form the first openings 4026.

After the second photoresist pattern 4020 is formed on the rear inorganic film 4500, an anisotropic etching process, e.g., an RIE process, may be performed using the second photoresist pattern 4020 as an etching mask, thereby forming the rear openings 4510 and the preliminary intermediate openings 4404 that penetrate the rear inorganic film 4500 and the intermediate inorganic film 4400, respectively.

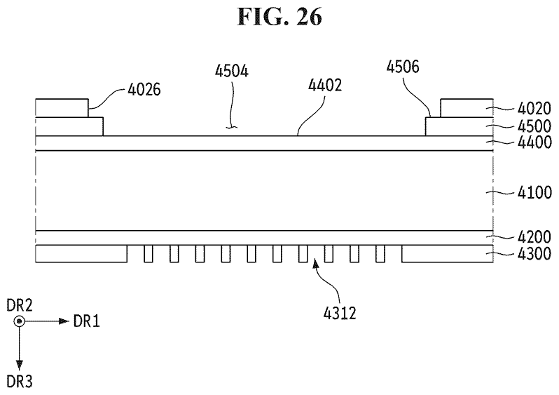

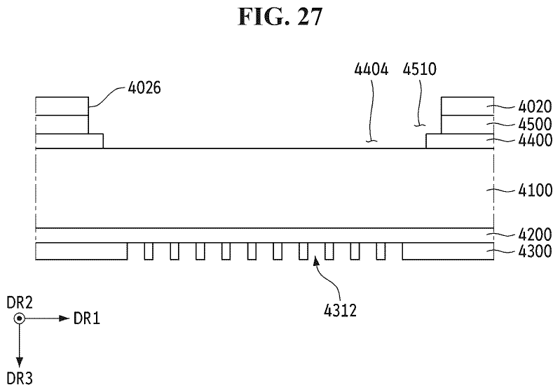

For example, as shown in FIG. 26, in one or more embodiments, portions 4502 (see FIG. 25) of the rear inorganic film 4500 exposed through the second openings 4028 may be removed, and preliminary rear openings 4504 may be formed to expose portions 4402 of the intermediate inorganic film 4400 where the preliminary intermediate openings 4404 are to be formed. In this regard, the preliminary rear openings 4504 may each have a smaller width than their corresponding rear openings 4510 (see FIG. 27). In these embodiments, the stepped portions 4024 of the pattern openings 4022 may be removed, and portions 4506 of the rear inorganic film 4500 having a ring shape may be exposed through the first openings 4026.

Subsequently, as shown in FIG. 27, the exposed portions 4402 of the intermediate inorganic film 4400 may be removed, thereby forming the preliminary intermediate openings 4404 that expose the rear portions of the mask substrate 4100. According to one or more embodiments, the preliminary intermediate openings 4404 may have the same width as their corresponding preliminary rear openings 4504. For example, the preliminary intermediate openings 4404 may have the same size and the same shape as their corresponding preliminary rear openings 4504.

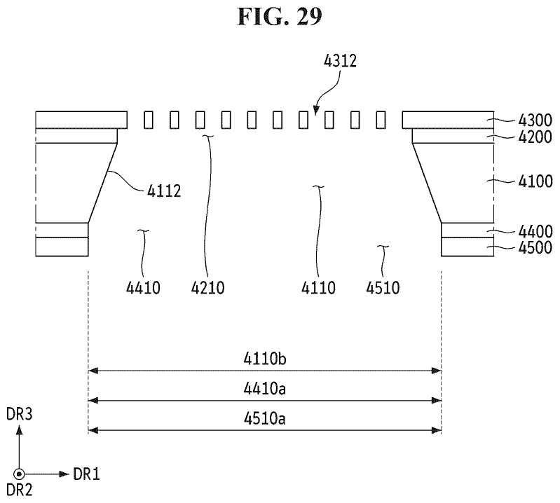

In addition, the exposed portions 4506 of the rear inorganic film 4500 may be removed, thereby forming the rear openings 4510 having the width 4510a (see FIG. 29) greater than their corresponding preliminary intermediate openings 4404. In this regard, the preliminary intermediate openings 4404 and the rear openings 4510 may be concurrently (e.g., simultaneously) formed. The second photoresist pattern 4020 may be removed by an ashing and/or stripping process after the preliminary intermediate openings 4404 and the rear openings 4510 are formed.

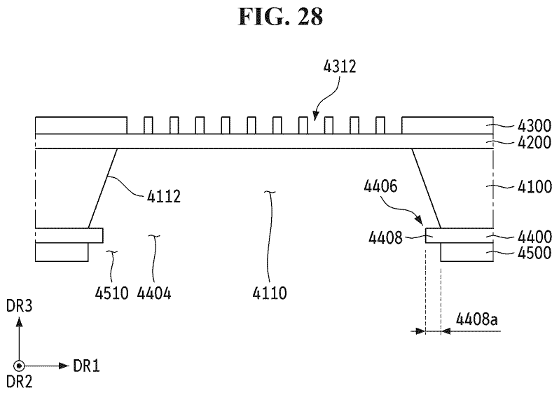

Referring to FIG. 28, the mask substrate 4100 may be partially removed to form the cell openings 4110 that expose the buffer inorganic film 4200. According to one or more embodiments, the cell openings 4110 may be formed through an anisotropic etching process that uses the rear inorganic film 4500 and the intermediate inorganic film 4400 as etching masks. For example, the cell openings 4110 may be formed by a wet etching process that uses an etchant such as a TMAH solution or a KOH solution, and the wet etching process may be performed until the buffer inorganic film 4200 is exposed.

According to one or more embodiments, the <100> crystal direction of the single crystal silicon substrate used as the mask substrate 4100 may be the third direction DR3, and accordingly, the cell openings 4110 may have a width that gradually decreases from the rear surface 4104 of the mask substrate 4100 toward the front surface 4102 of the mask substrate 4100 through the wet etching process. For example, inner side surfaces 4112 of the cell openings 4110 may have an inclination angle of about 54.7° with respect to the rear surface 4104 of the mask substrate 4100. This tapering profile results from the anisotropic etching characteristics of silicon, where the etch rate along the <100> direction is higher than along the <111> planes. As a result, the etching process naturally forms sloped sidewalls at an angle of about 54.7°, which corresponds to the angle between the <100> and <111> crystal planes. This geometry produces a trapezoidal or pyramidal cross-section that narrows toward the front surface, enabling precise and stable formation of the cell openings. According to one or more embodiments, during the wet etching process, etching may proceed in a <111> crystal direction of the mask substrate 4100, thereby forming undercut structures 4406 between the intermediate inorganic film 4400 and the cell openings 4110. In addition, portions 4408 of the intermediate inorganic film 4400 that define the preliminary intermediate openings 4404 may be exposed by the wet etching process. The exposed portions 4408 of the intermediate inorganic film 4400 may have a ring shape, and the undercut structures 4406 may be defined by the inner side surfaces 4112 of the cell openings 4110 and the exposed portions 4408 of the intermediate inorganic film 4400. For example, in one or more embodiments, the exposed portions 4408 of the intermediate inorganic film 4400 may have a width 4408a of about 30 μm to about 60 μm.

According to one or more embodiments, the buffer inorganic film 4200 may function as an etch stop film while forming the cell openings 411. For example, if (e.g., when) the buffer inorganic film 4200 is omitted, the etchant may be provided onto the front surface 4102 of the mask substrate 4100 through the pixel openings 4312, and hydrogen bubbles may be generated in the pixel openings 4312 by a reaction between the etchant and the mask substrate 4100. In this regard, the mask cell regions 4310 of the membrane 4300 may be damaged by the hydrogen bubbles. The buffer inorganic film 4200 may prevent (e.g., protect or reduce) an etchant from being provided onto the front surface 4102 of the mask substrate 4100 through the pixel openings 4312, thereby preventing or reducing damage to the membrane 4300.

Referring to FIG. 29, portions of the buffer inorganic film 4200 exposed through the cell openings 4110 may be removed, thereby forming the buffer openings 4210 that connect the pixel openings 4312 to the cell openings 4110. By way of example, in one or more embodiments, if (e.g., when) the buffer inorganic film 4200 includes silicon oxide (SiOₓ), the buffer openings 4210 may be formed by a wet etching process using an etchant such as BOE, diluted HF and/or the like.

According to one or more embodiments, the intermediate inorganic film 4400 may include the same material, e.g., silicon oxide (SiOₓ), as the buffer inorganic film 4200, and thus the exposed portions 4408 of the intermediate inorganic film 4400 may be removed while forming the buffer openings 4210. As a result, the undercut structures 4406 between the cell openings 4110 and the intermediate inorganic film 4400 may be removed, thereby reducing or preventing damage to the intermediate inorganic film 4400 during the deposition process and the ultrasonic cleaning process.

In addition, the preliminary intermediate openings 4404 may be expanded by removing the exposed portions 4408 of the intermediate inorganic film 4400, thereby forming the intermediate openings 4410 that connect the rear openings 4510 to the cell openings 4110. According to one or more embodiments, the width of the intermediate openings 4410 may be the same as the rear width 4110b of their corresponding cell openings 4110, and the width 4510a of the rear openings 4510 may be the same as the width 4410a of their corresponding intermediate openings 4410. For example, in one or more embodiments, the width 4510a of the rear openings 4510 may be the same as the rear width 4110b of their corresponding cell openings 4110. As another example, in one or more embodiments, the width 4510a of the rear openings 4510 may be greater than the rear width 4110b of their corresponding cell openings 4110.

According to one or more embodiments, the width 4510a of the rear openings 4510 may be determined by the width of their corresponding first openings 4026 of the second photoresist pattern 4020, and the width of the first openings 4026 may be equal to or greater than the rear width 4110b of their corresponding cell openings 4110. Therefore, damage to the rear inorganic film 4500 may be prevented or reduced during the deposition process or the ultrasonic cleaning process. In addition, the width 4510a of the rear openings 4510 may be equal to or greater than the rear width 4110b of their corresponding cell openings 4110, and accordingly, the amount of deposition material blocked by the rear inorganic film 4500 during the deposition process may be reduced.

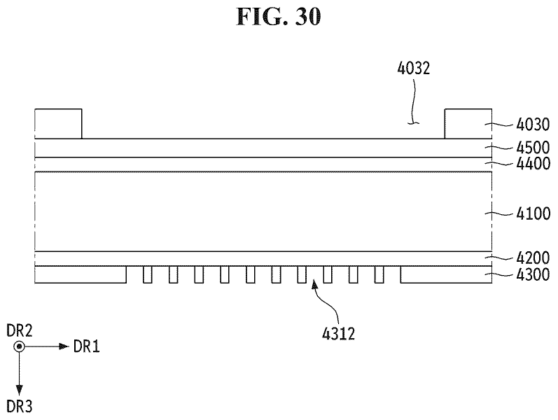

FIGS. 30 to 33 are schematic enlarged cross-sectional views illustrating a method of manufacturing a deposition mask according to one or more embodiments of the present disclosure.

According to one or more embodiments, the buffer inorganic film 4200 may be formed on the front surface 4102 (see FIG. 21) of the mask substrate 4100, and the intermediate inorganic film 4400 may be formed on the rear surface 4104 (see FIG. 21) of the mask substrate 4100. Subsequently, the membrane 4300 may be formed on the buffer inorganic film 4200, and the rear inorganic film 4500 may be formed on the intermediate inorganic film 4400. Additionally, the membrane 4300 may be patterned to form the plurality of pixel openings 4312 exposing the buffer inorganic film 4200. In this regard, the method of forming the buffer inorganic film 4200, the intermediate inorganic film 4400, the membrane 4300, the rear inorganic film 4500, and the pixel openings 4312 are substantially the same as described above with reference to FIGS. 21 to 24, and thus, detailed description thereof will not be provided for conciseness.

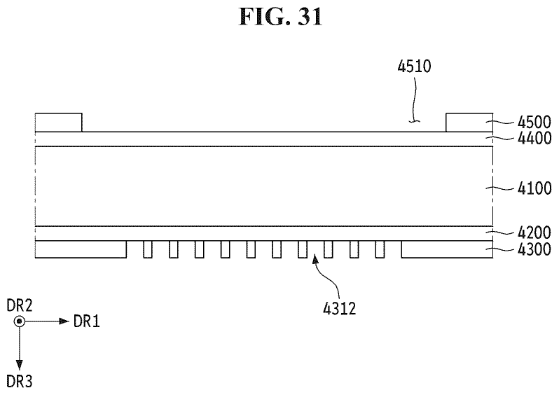

Referring to FIGS. 30 and 31, the rear inorganic film 4500 may be partially removed to form the rear openings 4510 that expose the intermediate inorganic film 4400. For example, as shown in FIG. 30, in one or more embodiments, a third photoresist pattern 4030 having pattern openings 4032 that expose portions where the rear openings 4510 are to be formed may be formed on the rear inorganic film 4500, and as shown in FIG. 31, an anisotropic etching process, e.g., an RIE process, may be performed using the third photoresist pattern 4030 as an etching mask, thereby forming the rear openings 4510 that expose the intermediate inorganic film 4400. The third photoresist pattern 4030 may be removed by an ashing and/or stripping process after the rear openings 4510 are formed.

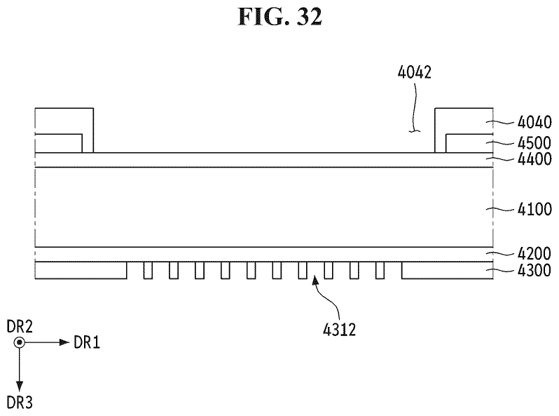

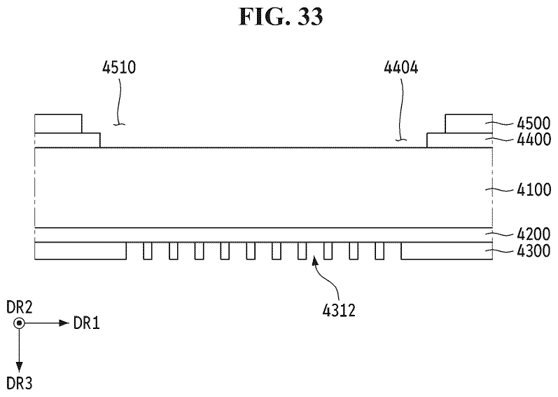

Referring to FIGS. 32 and 33, the intermediate inorganic film 4400 may be partially removed to form the preliminary intermediate openings 4404 that expose the rear surface 4104 of the mask substrate 4100. For example, as shown in FIG. 32, in one or more embodiments, a fourth photoresist pattern 4040 having pattern openings 4042 that expose portions where the preliminary intermediate openings 4404 are to be formed may be formed on the rear inorganic film 4500, and as shown in FIG. 33, an anisotropic etching process, e.g., an RIE process, may be performed using the fourth photoresist pattern 4040 as an etching mask, thereby forming the preliminary intermediate openings 4404 that expose the rear surface 4104 of the mask substrate 4100. The fourth photoresist pattern 4040 may be removed by an ashing and/or stripping process after forming the preliminary intermediate openings 4404. According to one or more embodiments, the preliminary intermediate openings 4404 may have a width smaller than that of their corresponding rear openings 4510, and may be respectively positioned within the rear openings 4510 in plan view.

After forming the rear openings 4510 and the preliminary intermediate openings 4404, as shown in FIG. 28, the cell openings 4110 that expose the buffer inorganic film 4200 through the mask substrate 4100 may be formed, and as shown in FIG. 29, the buffer openings 4210 that connect the cell openings 4110 to the pixel openings 4312 may be formed. According to one or more embodiments, during the formation of the cell openings 4110, the portions 4408 of the intermediate inorganic film 4400 that form the undercut structures 4406 between the cell openings 4110 and the intermediate inorganic film 4400 may be exposed, and the exposed portions 4408 of the intermediate inorganic film 4400 may be removed during the formation of the buffer openings 4210. In the present embodiments, the method of forming the cell openings 4110 and the buffer openings 4210 and the method of removing the exposed portions 4408 of the intermediate inorganic film 4400 are substantially the same as those described above with reference to FIGS. 28 and 29, and thus detailed descriptions thereof will not be provided for conciseness.

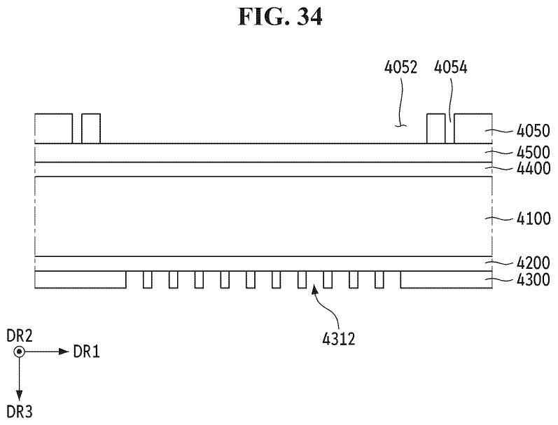

FIGS. 34 to 38 are schematic enlarged cross-sectional views illustrating a method of manufacturing a deposition mask according to one or more embodiments of the present disclosure.

According to one or more embodiments, the buffer inorganic film 4200 may be formed on the front surface 4102 (see FIG. 21) of the mask substrate 4100, and the intermediate inorganic film 4400 may be formed on the rear surface 4104 (see FIG. 21) of the mask substrate 4100. Subsequently, the membrane 4300 may be formed on the buffer inorganic film 4200, and the rear inorganic film 4500 may be formed on the intermediate inorganic film 4400. Additionally, the membrane 4300 may be patterned to form the plurality of pixel openings 4312 exposing the buffer inorganic film 4200. In this regard, the method of forming the buffer inorganic film 4200, the intermediate inorganic film 4400, the membrane 4300, the rear inorganic film 4500, and the pixel openings 4312 are substantially the same as described above with reference to FIGS. 21 to 24, and thus, detailed description thereof will not be provided for conciseness.

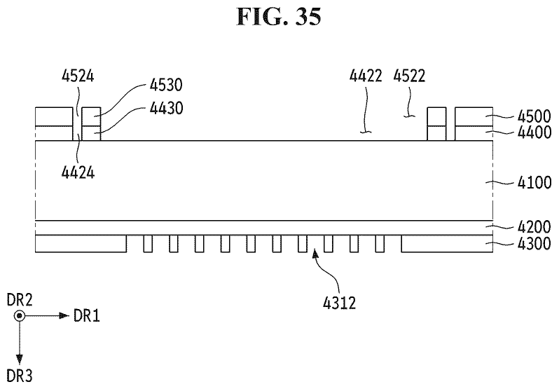

Referring to FIG. 34 and FIG. 35, the rear inorganic film 4500 and the intermediate inorganic film 4400 may be partially removed to form first preliminary rear openings 4522, first preliminary intermediate openings 4422, second preliminary rear openings 4524, and second preliminary intermediate openings 4424 that expose the rear surface 4104 of the mask substrate 4100.

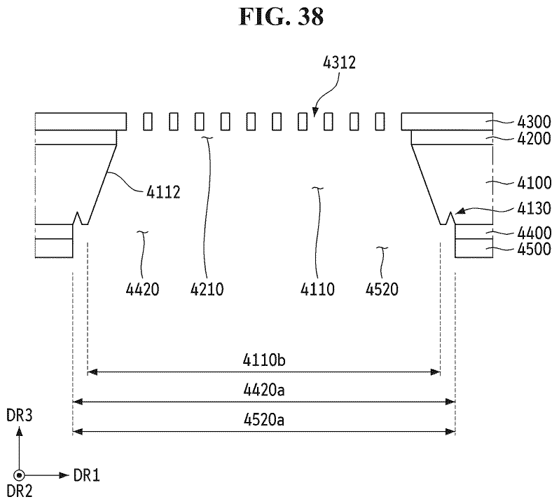

According to one or more embodiments, as shown in FIG. 34, a fifth photoresist pattern 4050 having first pattern openings 4052 that expose portions where the first preliminary rear openings 4522 are to be formed and second pattern openings 4054 that expose portions where the second preliminary rear openings 4524 are to be formed may be formed on the rear inorganic film 4500. For example, the first pattern openings 4052 may be formed to correspond to the cell openings 4110, and the second pattern openings 4054 may have a ring shape around (e.g., surrounding) the first pattern openings 4052. For example, in one or more embodiments, the first pattern openings 4052 may have a width smaller than the rear width 4110b (see FIG. 38) of their corresponding cell openings 4110, and the second pattern openings 4054 may be spaced apart (e.g., spaced or apart) from their corresponding first pattern openings 4052 by a selected or set distance. For example, in one or more embodiments, the second pattern openings 4054 may be spaced apart from their corresponding first pattern openings 4052 by about 30 μm to about 60 μm, and may have a width of about 1 μm to about 10 μm.

Referring to FIG. 35, an anisotropic etching process, e.g., an RIE process, may be performed using the fifth photoresist pattern 4050 as an etching mask, thereby forming the first preliminary rear openings 4522 and the second preliminary rear openings 4524 that penetrate the rear inorganic film 4500, and forming the first preliminary intermediate openings 4422 and the second preliminary intermediate openings 4424 that penetrate the intermediate inorganic film 4400.

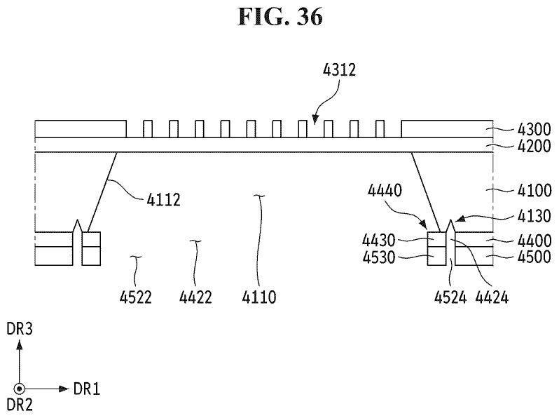

According to one or more embodiments, the first preliminary rear openings 4522 and the first preliminary intermediate openings 4422 may expose the rear portions of the mask substrate 4100 where the cell openings 4110 are to be formed, and the second preliminary rear openings 4524 and the second preliminary intermediate openings 4424 may expose the rear portions of the mask substrate 4100 where the ring-shaped grooves 4130 (see FIG. 36) are to be formed. For example, the first preliminary rear openings 4522 and the first preliminary intermediate openings 4422 may each have a width smaller than the rear width 4110b of their corresponding cell openings 4110, and the second preliminary rear openings 4524 and the second preliminary intermediate openings 4424 may have a ring shape around (e.g., surrounding) the first preliminary rear openings 4522 and the first preliminary intermediate openings 4422.

According to one or more embodiments, ring-shaped rear patterns 4530 may be formed between the first preliminary rear openings 4522 and the second preliminary rear openings 4524. For example, in one or more embodiments, the rear patterns 4530 may have a width of about 30 μm to about 60 μm, and may be defined by the first preliminary rear openings 4522 and the second preliminary rear openings 4524. In addition, ring-shaped intermediate patterns 4430 may be formed between the first preliminary intermediate openings 4422 and the second preliminary intermediate openings 4424. For example, in one or more embodiments, the intermediate patterns 4430 may have a width of about 30μm to about 60μm, and may be defined by the first preliminary intermediate openings 4422 and the second preliminary intermediate openings 4424. After the first preliminary rear openings 4522, the second preliminary rear openings 4524, the first preliminary intermediate openings 4422, and the second preliminary intermediate openings 4424 are formed, the fifth photoresist pattern 4050 may be removed by an ashing and/or stripping process.

Referring to FIG. 36, the mask substrate 4100 may be partially removed to form the cell openings 4110 that expose the buffer inorganic film 4200 and the ring-shaped grooves 4130 around (e.g., surrounding) their corresponding cell openings 4110. For example, the cell openings 4110 and the grooves 4130 may be formed by a wet etching process that uses an etchant such as a TMAH solution or a KOH solution. According to one or more embodiments, portions of the mask substrate 4100 exposed through the first preliminary rear openings 4522 and the first preliminary intermediate openings 4422 may be removed by the etchant, thereby forming the cell openings 4110. In addition, portions of the mask substrate 4100 exposed through the second preliminary rear openings 4524 and the second preliminary intermediate openings 4424 may be removed by the etchant, thereby forming the grooves 4130.

According to one or more embodiments, the inner side surfaces 4112 of the cell openings 4110 may have an inclination angle of about 54.7° with respect to the rear surface 4104 of the mask substrate 4100, and the rear width 4110b of the cell openings 4110 may be formed to be greater than the widths of their corresponding first preliminary rear openings 4522 and first preliminary intermediate openings 4422 by the wet etching process. In addition, the undercut structures 4440 may be formed between the intermediate patterns 4430 and the cell openings 4110 while forming the cell openings 4110.

Each of the grooves 4130 may have inner side surfaces connected to each other, and the inner side surfaces of each of the grooves 4130 may have an inclination angle of about 54.7° with respect to the rear surface of the mask substrate 4100. In these embodiments, because the cell openings 4110 and the grooves 4130 and the method of forming the cell openings 4110 and the grooves 4130 are substantially the same as described above with reference to FIGS. 20 and 28, description thereof will not be provided for conciseness.

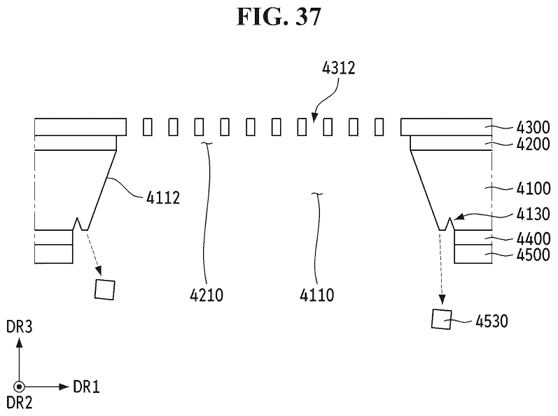

Referring to FIG. 37 and FIG. 38, portions of the buffer inorganic film 4200 exposed through the cell openings 4110 may be removed to form the buffer openings 4210 that connect the cell openings 4110 to the pixel openings 4312. According to one or more embodiments, if (e.g., when) the buffer inorganic film 4200 includes silicon oxide (SiOₓ), the buffer openings 4210 may be formed by a wet etching process using an etchant such as BOE, diluted HF and/or the like.

According to one or more embodiments, if (e.g., when) the intermediate inorganic film 4400 includes silicon oxide (SiOₓ), the intermediate patterns 4430 may be removed by an etchant such as BOE or diluted HF during the formation of the buffer openings 4210, and accordingly, as shown in FIG. 37, the rear patterns 4530 may be separated and removed from the mask substrate 4100. As a result, the first preliminary rear openings 4522 and the second preliminary rear openings 4524 may communicate with each other, and the first preliminary intermediate openings 4422 and the second preliminary intermediate openings 4424 may communicate with each other, and accordingly, the rear openings 4520 and the intermediate openings 4420 that expose the cell openings 4110 and the grooves 4130 may be formed.

As described above, as the rear pattern 4530 and the intermediate pattern 4430 are removed, each of the rear openings 4520 may be formed to include the first preliminary rear opening 4522 and the second preliminary rear opening 4524, and each of the intermediate openings 4420 may be formed to include the first preliminary intermediate opening 4422 and the second preliminary intermediate opening 4424. In addition, the width 4520a of the rear openings 4520 may be the same as the width 4420a of their corresponding intermediate openings 4420, and the width 4420a of the intermediate openings 4420 may be greater than the rear width 4110b of their corresponding cell openings 4110.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The display module, the display device, the electronic device/apparatus, the deposition mask-manufacturing apparatus, the vacuum-deposition apparatus such as a thermal deposition apparatus, an E-beam evaporator, a chemical vapor deposition apparatus, and/or the like, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The disclosure should not be construed as being limited to the embodiments set forth herein. Rather, these embodiments are provided so that this disclosure will be thorough and complete and will fully convey the concept of the present disclosure to those skilled in the art.

While the present disclosure has been particularly shown and described with reference to one or more embodiments thereof, it will be understood by those of ordinary skill in the art that one or more suitable changes in form and details may be made therein without departing from the spirit or scope of the disclosure as defined by the appended claims and equivalents thereof.

What is claimed is:

1. A deposition mask comprising:
a mask substrate having a cell opening;
a membrane on a front surface of the mask substrate and having a plurality of pixel openings communicating with the cell opening; and
a rear inorganic film on a rear surface of the mask substrate and having a rear opening communicating with the cell opening,
wherein a width of the rear opening is equal to or greater than a width of the cell opening.

2. The deposition mask of claim 1, wherein the width of the cell opening comprises a front width adjacent to the membrane and a rear width adjacent to the rear inorganic film, and
the width of the rear opening is equal to or greater than the rear width of the cell opening.

3. The deposition mask of claim 1, further comprising an intermediate inorganic film between the mask substrate and the rear inorganic film and having an intermediate opening between the cell opening and the rear opening,
wherein a width of the intermediate opening is equal to or greater than the width of the cell opening.

4. The deposition mask of claim 3, further comprising a buffer inorganic film between the mask substrate and the membrane and having a buffer opening between the cell opening and the pixel openings,
wherein the intermediate inorganic film comprises a same material as the buffer inorganic film.

5. The deposition mask of claim 1, wherein the mask substrate has a ring-shaped groove in a rear portion of the mask substrate to surround the cell opening.

6. A method, comprising:
forming a membrane having a plurality of pixel openings on a front surface of a mask substrate;
forming a rear inorganic film on a rear surface of the mask substrate;
partially removing the rear inorganic film to form a rear opening; and
partially removing the mask substrate to form a cell opening between the pixel openings and the rear opening,
wherein the rear opening has a width equal to or greater than a width of the cell opening, and
wherein the method is a method of manufacturing a deposition mask.

7. The method of claim 6, further comprising forming an intermediate inorganic film on the rear surface of the mask substrate,
wherein the rear inorganic film is formed on the intermediate inorganic film.

8. The method of claim 7, further comprising:
partially removing the rear inorganic film to form a preliminary rear opening having a smaller width than the rear opening; and
partially removing the intermediate inorganic film to form a preliminary intermediate opening having a same width as the preliminary rear opening,
wherein the preliminary intermediate opening and the rear opening are formed concurrently.

9. The method of claim 8, further comprising forming a photoresist pattern having a pattern opening comprising a first opening corresponding to the rear opening and a second opening corresponding to the preliminary intermediate opening on the rear inorganic film,
wherein the preliminary rear opening, the preliminary intermediate opening, and the rear opening are each formed by an anisotropic etching process utilizing the photoresist pattern as an etching mask.

10. The method of claim 9, wherein the photoresist pattern is formed by a photolithography process utilizing a halftone mask.

11. The method of claim 8, wherein while forming the cell opening, a portion of the intermediate inorganic film defining the preliminary intermediate opening is exposed, and an undercut structure is formed between the cell opening and the exposed portion of the intermediate inorganic film.

12. The method of claim 11, further comprising removing the exposed portion of the intermediate inorganic film to form an intermediate opening between the cell opening and the rear opening.

13. The method of claim 7, further comprising partially removing the intermediate inorganic film to form a preliminary intermediate opening having a smaller width than the rear opening.

14. The method of claim 7, further comprising:
partially removing the rear inorganic film to form a first preliminary rear opening, a second preliminary rear opening in a ring shape around the first preliminary rear opening, and a rear pattern in a ring shape defined by the first preliminary rear opening and the second preliminary rear opening; and
partially removing the intermediate inorganic film to form a first preliminary intermediate opening, a second preliminary intermediate opening in a ring shape around the first preliminary intermediate opening, and an intermediate pattern in a ring shape defined by the first preliminary intermediate opening and the second preliminary intermediate opening.

15. The method of claim 14, wherein the cell opening is formed by removing a portion of the mask substrate exposed by the first preliminary rear opening and the first preliminary intermediate opening.

16. The method of claim 15, wherein while forming the cell opening, an undercut structure is formed between the cell opening and the intermediate pattern.

17. The method of claim 14, further comprising removing a portion of the mask substrate exposed by the second preliminary rear opening and the second preliminary intermediate opening to form a ring-shaped groove around the cell opening.

18. The method of claim 14, further comprising removing the intermediate pattern to form an intermediate opening comprising the first preliminary intermediate opening and the second preliminary intermediate opening.

19. The method of claim 18, wherein the rear pattern is separated and removed from the mask substrate by removing the intermediate pattern, and
the rear opening is formed to comprise the first preliminary rear opening and the second preliminary rear opening as the rear pattern is removed from the mask substrate.

20. An electronic device comprising a display panel,
wherein the display panel comprises a backplane substrate and light emitting layers formed on the backplane substrate utilizing a deposition mask, and
the deposition mask comprises:
a mask substrate having a cell opening;
a membrane on a front surface of the mask substrate and having a plurality of pixel openings communicating with the cell opening; and
a rear inorganic film on a rear surface of the mask substrate and having a rear opening communicating with the cell opening,
wherein the rear opening has a width equal to or greater than a width of the cell opening.
